(19) United States
(12) Patent Application Publication
(10) Pub. No.: US 2022/0295672 A1
(43) Pub. Date: Sep. 15, 2022

(54) POWER CONVERSION DEVICE AND MANUFACTURING METHOD THEREFOR

(71) Applicant: Mitsubishi Electric Corporation, Tokyo (JP)

(72) Inventor: Shota YAMABE, Tokyo (JP)

(73) Assignee: Mitsubishi Electric Corporation, Tokyo (JP)

(21) Appl. No.: 17/458,749

(22) Filed: Aug. 27, 2021

(30) Foreign Application Priority Data
Mar. 9, 2021 (JP) 2021-036910

(51) Int. Cl. H05K 7/20; H02M 1/32

(52) U.S. Cl. CPC H05K 7/20927; H02M 1/327; H05K 7/20254

(57) ABSTRACT

The power conversion device includes: a power module having a shape of a rectangular parallelepiped; a cooling plate; and a cooler. The cooler includes: a cooling flow path through which a coolant flows; a first flow path hole extending from a third side surface side to a fourth side surface side; a second flow path hole extending from the third side surface side to the fourth side surface side; a first coupling portion coupling the cooling flow path and the first flow path hole; and a second coupling portion coupling the cooling flow path and the second flow path hole. The power module and each of at least a part of the first flow path hole and at least a part of the second flow path hole are located to overlap with each other as seen in a direction perpendicular to another surface of the cooling plate.

### BACKGROUND OF THE INVENTION

### 1. Field of the Invention

The present disclosure relates to a power conversion device and a manufacturing method therefor.

### 2. Description of the Background Art

Driving motors are used for motorized vehicles, specifically, hybrid vehicles (HVs), plug-in hybrid vehicles (PHVs and PHEVs), electric vehicles (EVs), and fuel cell vehicles (FCVs). Such motorized vehicles are mounted with power conversion devices such as inverters for driving the driving motors and converters for stepping up voltages of batteries. Such a power conversion device includes: a power module mounted with a power semiconductor; a cooler for cooling the power module; a capacitor; and the like. The cooler is provided with a flow path through which a coolant flows.

Size reduction and output increase of, and cost reduction for, the power conversion device tend to be required in recent years, and thus current flowing to, and voltage applied to, a chip of the power semiconductor have been becoming high every year. In addition, the proportion of cost for the semiconductor chip to cost for the power conversion device is high, and thus cost reduction for the semiconductor chip is required.

Studies have been conducted for improving cooling capability for such a semiconductor chip in order to reduce cost for the semiconductor chip. For example, a power module mounted with a semiconductor chip, and a cooler which cools both surfaces of the power module and which is composed of a plurality of components, have been disclosed (see, for example, Patent Document 1). In the disclosed structure, the cooler integrated with the power module is used and disposed in a hollow housing together with a capacitor.
Patent Document 1: Japanese Laid-Open Patent Publication No. 2015-109322

In the above Patent Document 1, both surfaces of the power module mounted with the semiconductor chip can be cooled. However, the power module and the cooler are integrally formed by using a plurality of components, and thus a problem arises in that the positional relationship between, and the sizes of, the power module and the cooler impose restrictions on arrangement of the components, whereby size reduction is difficult.

In addition, the following problem also arises. That is, the degree of freedom in arrangement of a flow path of the cooler is low, and it is not easy to cool components other than the power module (for example, the capacitor) and change an inlet and an outlet for a coolant. Consequently, a complex piping route is necessary for changing the arrangement of the flow path, and thus it takes a number of steps to design the piping route and it takes time to make deliberation and correction for the designing. Therefore, cost reduction is difficult.

### SUMMARY OF THE INVENTION

Considering this, an object of the present disclosure is to obtain a power conversion device in which the degree of freedom in arrangement of a power module and a cooler and arrangement of a flow path of the cooler is high, and which has a small size and requires low cost.

A power conversion device according to the present disclosure includes: a power module including a power semiconductor and having a shape of a rectangular parallelepiped having a bottom surface, a top surface, and four side surfaces; a flat-shaped cooling plate having one surface thermally connected to the bottom surface of the power module; and a cooler configured to cool the cooling plate. The cooler includes: a cooling flow path through which a coolant flows, along another surface of the cooling plate, from a first side surface side of the power module to a second side surface side thereof opposite to the first side surface; a first flow path hole disposed apart from the cooling flow path so as to be closer to an opposite side to the power module side than a portion of the cooling flow path on the first side surface side is, and extending from a third side surface side of the power module adjacent to the first side surface to a fourth side surface side thereof opposite to the third side surface; a second flow path hole disposed apart from the cooling flow path so as to be closer to the opposite side to the power module side than a portion of the cooling flow path on the second side surface side is, and extending from the third side surface side to the fourth side surface side; a first coupling portion coupling the first flow path hole and the portion of the cooling flow path on the first side surface side; and a second coupling portion coupling the second flow path hole and the portion of the cooling flow path on the second side surface side. The power module and each of at least a part of the first flow path hole and at least a part of the second flow path hole are located to overlap with each other as seen in a direction perpendicular to the one surface of the cooling plate.

The power conversion device according to the present disclosure includes: a power module; a flat-shaped cooling plate having one surface thermally connected to the bottom surface of the power module; and a cooler configured to cool the cooling plate. The cooler includes: a cooling flow path through which a coolant flows along another surface of the cooling plate; a first flow path hole and a second flow path hole disposed apart from the cooling flow path; a first coupling portion coupling the cooling flow path and the first flow path hole; and a second coupling portion coupling the cooling flow path and the second flow path hole. The power module and each of at least a part of the first flow path hole and at least a part of the second flow path hole are located to overlap with each other as seen in a direction perpendicular to the one surface of the cooling plate. Consequently, the projection area of the cooler can be reduced, and thus the size of the power conversion device can be reduced. In addition, since the power module is disposed on the cooling plate, the degree of freedom in arrangement of the power module and the cooler is high, and this arrangement does not influence the degree of freedom in arrangement of other components. Therefore, the size of the power conversion device can be easily reduced. In addition, since the configuration of the flow path of the cooler is simple, the degree of freedom in arrangement of the flow path of the cooler can be increased, and cost for the power conversion device can be reduced.

### BRIEF DESCRIPTION OF THE DRAWINGS

FIG. 1 is a plan view of a power conversion device according to a first embodiment;

FIG. 2 is a cross-sectional view of the power conversion device taken at the cross-sectional position A-A in FIG. 1;

FIG. 3 is another plan view of the power conversion device according to the first embodiment;

FIG. 4 is a cross-sectional view of the power conversion device taken at the cross-sectional position B-B in FIG. 3;

FIG. 5 is a cross-sectional view of the power conversion device taken at the cross-sectional position C-C in FIG. 3;

FIG. 6 is a cross-sectional view of another power conversion device taken at the cross-sectional position C-C in FIG. 3;

FIG. 7 illustrates a manufacturing process for the power conversion device according to the first embodiment;

FIG. 8 is a cross-sectional view of another power conversion device taken at the cross-sectional position A-A in FIG. 1;

FIG. 9 is a plan view of a power conversion device according to a second embodiment;

FIG. 10 is a cross-sectional view of the power conversion device taken at the cross-sectional position D-D in FIG. 9;

FIG. 11 is a plan view of a power conversion device according to a third embodiment;

FIG. 12 is a cross-sectional view of the power conversion device taken at the cross-sectional position E-E in FIG. 11;

FIG. 13 is a plan view of a power conversion device according to a fourth embodiment;

FIG. 14 is a cross-sectional view of the power conversion device taken at the cross-sectional position F-F in FIG. 13;

FIG. 15 is a cross-sectional view of a power conversion device according to a fifth embodiment;

FIG. 16 is a side view of a power conversion device according to a sixth embodiment;

FIG. 17 is a cross-sectional view of the power conversion device taken at the cross-sectional position G-G in FIG. 16;

FIG. 18 is a plan view of a power conversion device according to a seventh embodiment;

FIG. 19 is a cross-sectional view of the power conversion device taken at the cross-sectional position H-H in FIG. 18;

FIG. 20 is a cross-sectional view of the power conversion device taken at the cross-sectional position J-J in FIG. 18;

FIG. 21 is a cross-sectional view of the power conversion device taken at the cross-sectional position K-K in FIG. 18;

FIG. 22 is a cross-sectional view of the power conversion device taken at the cross-sectional position H-H in FIG. 18;

FIG. 23 is a cross-sectional view of the power conversion device taken at the cross-sectional position J-J in FIG. 18;

FIG. 24 is a plan view of a power conversion device according to an eighth embodiment;

FIG. 25 is a cross-sectional view of the power conversion device taken at the cross-sectional position L-L in FIG. 24;

FIG. 26 is a cross-sectional view of the power conversion device taken at the cross-sectional position M-M in FIG. 24;

FIG. 27 is a cross-sectional view of the power conversion device taken at the cross-sectional position N-N in FIG. 24;

FIG. 28 is a cross-sectional view of the power conversion device taken at the cross-sectional position M-M in FIG. 24; and

FIG. 29 is a cross-sectional view of another power conversion device taken at the cross-sectional position L-L in FIG. 24.

### DETAILED DESCRIPTION OF THE PREFERRED EMBODIMENTS OF THE INVENTION

Hereinafter, power conversion devices according to embodiments of the present disclosure will be described with reference to the drawings. Description will be given while the same or corresponding members and portions in the drawings are denoted by the same reference characters.

### First Embodiment

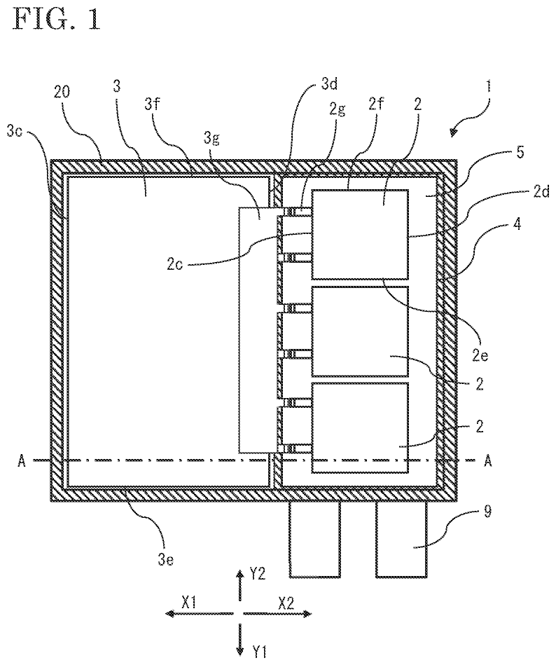

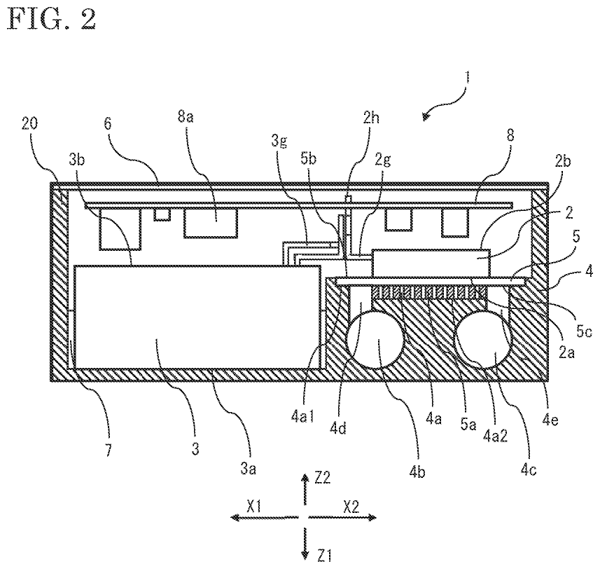

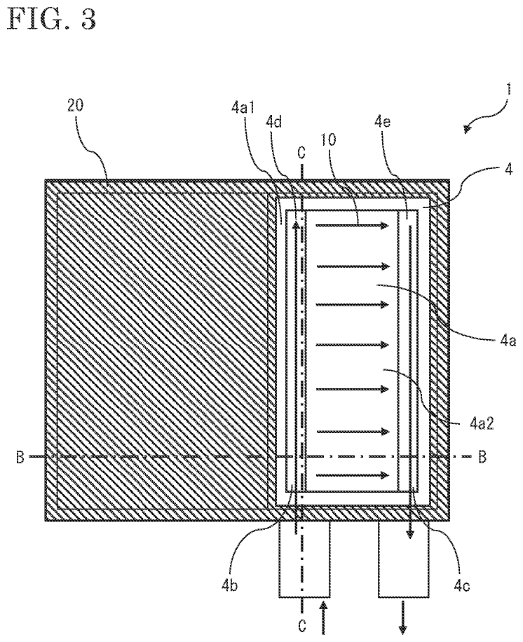

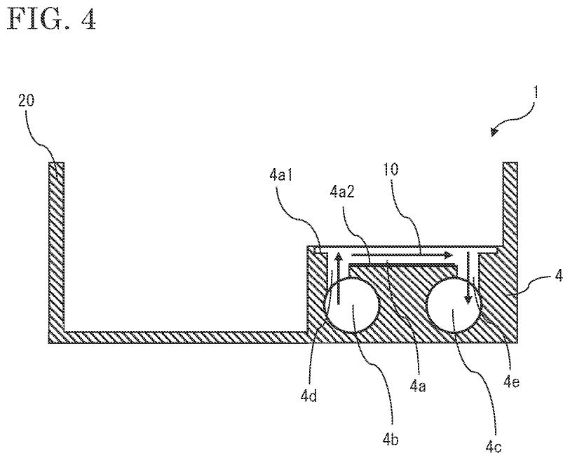

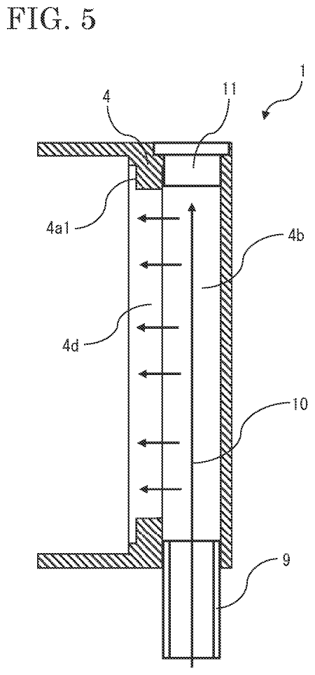

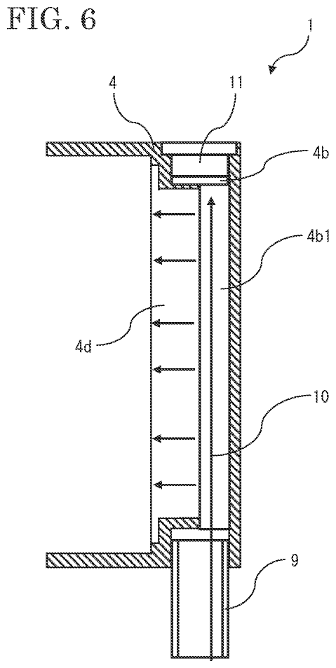

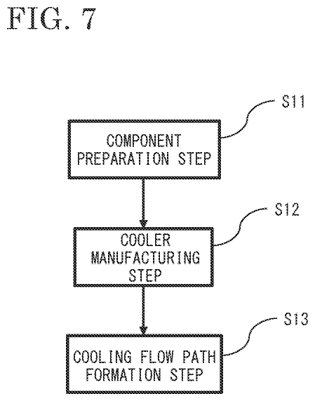

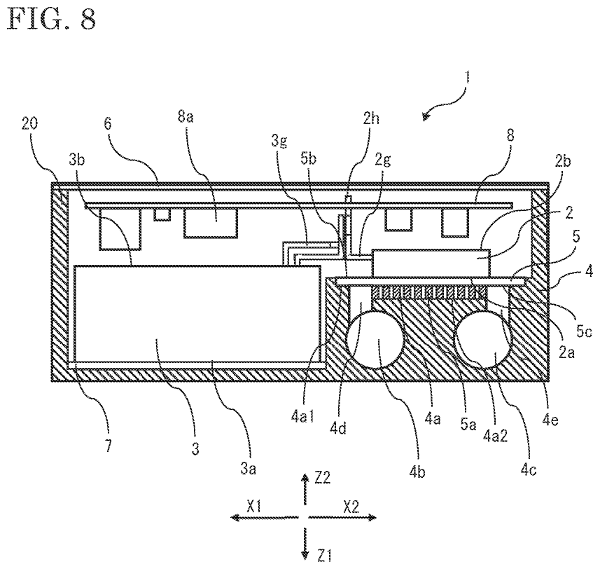

FIG. 1 is a plan view of a power conversion device 1 according to a first embodiment, excluding a lid 6 and a control board 8. FIG. 2 is a cross-sectional view of the power conversion device 1 taken at the cross-sectional position A-A in FIG. 1, including the lid 6 and the control board 8. FIG. 3 is another plan view of the power conversion device 1 and shows a cooler 4 and an outer wall member 20 while excluding internal components from FIG. 1. FIG. 4 is a cross-sectional view of the power conversion device 1 taken at the cross-sectional position B-B in FIG. 3. FIG. 5 is a cross-sectional view of the power conversion device 1 taken at the cross-sectional position C-C in FIG. 3. FIG. 6 is a cross-sectional view of another power conversion device 1 taken at the cross-sectional position C-C in FIG. 3. FIG. 7 illustrates a manufacturing process for the power conversion device 1 according to the first embodiment. FIG. 8 is a cross-sectional view of another power conversion device 1 taken at the cross-sectional position A-A in FIG. 1. The arrows shown in FIG. 3 to FIG. 6 indicate the direction in which a coolant flows (flowing direction 10). The power conversion device 1 has a circuit for controlling power, and converts input current from direct current to alternating current or from alternating current to direct current or converts input voltage to a different voltage.

<Component Configuration of Power Conversion Device 1>

As shown in FIG. 2, the power conversion device 1 includes power modules 2, a capacitor 3, the cooler 4, a cooling plate 5, the control board 8, and the lid 6. A member forming a flow path of the cooler 4 is formed integrally with the outer wall member 20 which encloses components such as the capacitor 3. It is noted that the drawings introduced in the embodiments do not show any opening portions for electrical input and output in the power conversion device 1. The power modules 2, the capacitor 3, the control board 8, and other low-heat-generation components (not shown) are accommodated in a space sealed by the cooler 4 and the lid 6 and are electrically connected to one another.

Each power module 2 includes therein a power semiconductor (not shown) and has the shape of a rectangular parallelepiped having a bottom surface 2a, a top surface 2b, and four side surfaces (a first side surface 2c, a second side surface 2d, a third side surface 2e, and a fourth side surface 2f). The power modules 2 in the present embodiment are disposed as shown in FIG. 1. That is, three power modules 2 are disposed side by side in a direction parallel to each first side surface 2c so as to have the same orientation. A length on the first side surface 2c side obtained by summing the lengths in the long-side direction of the first side surfaces 2c of the three power modules 2 is longer than the length of each power module 2 on the third side surface 2e side adjacent to the first side surfaces 2c. The first side surface 2c side and the third side surface 2e side refer to sides in directions that are parallel to normal directions to the respective side surfaces. That is, in FIG. 1, the first side surface 2c side refers to the side indicated by the arrow X1, and the third side surface 2e side refers to the side indicated by the arrow Y1. Likewise, in FIG. 1, the second side surface 2d side refers to the side indicated by the arrow X2, and the fourth side surface 2f side refers to the side indicated by the arrow Y2. Further, in FIG. 2, the bottom surface 2a side refers to the side indicated by the arrow Z1, and the top surface 2b side refers to the side indicated by the arrow Z2. The bottom surfaces 2a of all the power modules 2 are thermally connected to one surface 5b of the cooling plate 5. The number of the power modules 2 is not limited to three, and may be one or may be more than three. Each power module 2 includes power terminals 2g and control terminals 2h exposed outward. The power terminals 2g are connected to the capacitor 3, and the control terminals 2h are connected to the control board 8. In addition, the power module 2 is provided by, for example, mounting one or more power semiconductors on a substrate disposed inside. The number of the substrates is not limited to one, and it is also possible to employ a configuration in which the one or more power semiconductors are mounted on each of a plurality of the substrates.

The capacitor 3 is electrically connected to the power module 2 and disposed on: the first side surface 2c side of the power module 2; the second side surface 2d side of the power module 2 opposite to the first side surface 2c; or the top surface 2b side of the power module 2. In the present embodiment, the capacitor 3 is formed in the shape of a rectangular parallelepiped having a bottom surface 3a, a top surface 3b, and four side surfaces (a first side surface 3c, a second side surface 3d, a third side surface 3e, and a fourth side surface 3f). The capacitor 3 is disposed on the first side surface 2c side of the power module 2. One surface in the long-side direction of the capacitor 3 opposes the first side surface 2c side of the power module 2. The shape of the capacitor 3 is not limited to the shape of a rectangular parallelepiped and may be a cylindrical shape. The capacitor 3 is a component obtained by accommodating a plurality of elements in a capacitor case and injecting heat-dissipating resin into gaps between the elements and the capacitor case. The capacitor 3 includes a power terminal 3g exposed outward from the top surface 3b. The power terminal 3g is connected to the power terminals 2g of the power module 2.

In the present embodiment, the capacitor 3 is disposed such that the second side surface 3d thereof opposes the cooler 4. The outer wall member 20 encloses the first side surface 3c, the third side surface 3e, the fourth side surface 3f, and the bottom surface 3a of the capacitor 3. Gaps are present between the outer wall member 20 and the four side surfaces of the capacitor 3, and the gaps are filled with heat-dissipating resin 7 (for example, potting material). Since the gaps are filled with the heat-dissipating resin 7, the capacitor 3 can be efficiently cooled. Thus, the thermally weak capacitor 3 can be efficiently protected. The outer wall member 20 and the bottom surface 3a of the capacitor 3 are in contact with each other, and the capacitor 3 is attached to the bottom surface 3a by, for example, screwing. The capacitor 3 may be disposed on the second side surface 2d side of the power module 2 such that a surface in the long-side direction of the capacitor 3 opposes the second side surface 2d side of the power module 2. In addition, a configuration shown in FIG. 8 may be employed in which, instead of the gaps between the outer wall member 20 and the four side surfaces of the capacitor 3, the interval between the outer wall member 20 and the bottom surface 3a of the capacitor 3 is filled with the heat-dissipating resin 7. In this configuration, the use amount of the heat-dissipating resin 7 can be reduced, and thus cost for the heat-dissipating resin 7 can be reduced. It is noted that, if cooling of the capacitor 3 is insufficient with only the heat-dissipating resin 7 at the interval with the bottom surface 3a, the capacitor 3 only has to be cooled with the heat-dissipating resin 7 being provided in the intervals between the outer wall member 20 and the four side surfaces of the capacitor 3.

The control board 8 outputs a signal for controlling an operation of each power module 2, to control the operation of the power module 2. The control board 8 is mounted with a plurality of control components 8a, and the control terminals 2h are electrically connected to the control board 8. The control board 8 is disposed to oppose the power module 2 and the capacitor 3. By thus disposing the control board 8, the size of the power conversion device 1 can be reduced, and reduction in the inductance of the power conversion device 1 can be realized. The power terminals 2g of the power module 2 and the power terminal 3g of the capacitor 3 are electrically connected between the control board 8 and each of the power module 2 and the capacitor 3. By the connections at the positions, electrical wiring between the power module 2 and the capacitor 3 can be made shortest, and reduction in the inductance of the power conversion device 1 can be realized. The power terminals 2g and the power terminal 3g are connected to each other by, for example, welding, screw tightening, or laser welding. If the power terminals 2g and the power terminal 3g are electrically connected to each other directly by welding, screw tightening, laser welding, or the like without using another member, the electrical wiring is shortened, whereby both terminals can be connected to each other at low inductance. Since both terminals can be connected to each other at low inductance, the chip size of each power semiconductor can be reduced, whereby cost for the power semiconductor can be reduced.

The cooling plate 5 has a flat shape, and the one surface 5b thereof is thermally connected to the bottom surface 2a of the power module 2. Another surface 5c of the cooling plate 5 is joined to an outer peripheral portion 4al of a cooling flow path 4a described later, by metal joining (for example, friction stir welding). Cooling fins 5a are provided on the other surface 5c of the cooling plate 5. A plurality of the cooling fins 5a are provided so as to protrude in a direction away from the other surface 5c of the cooling plate 5. By providing the cooling fins 5a, the power module 2 can be efficiently cooled. The cooling plate 5 and the cooling fins 5a are each formed of a metal that has a high thermal conductivity, such as aluminum. If the intervals between the cooling fins 5a are narrowed, the area of contact between a coolant and the cooling fins 5a is increased, whereby heat dissipation from the power module 2 can be improved. The cooling fins 5a with narrowed intervals therebetween can be formed by, for example, forging. Meanwhile, if the cooling fins 5a have narrowed intervals therebetween to have an increased occupation rate, the cross-sectional area of a flow path through which a coolant flows is reduced. If the cross-sectional area of the flow path is reduced, the fluid resistance of the coolant is increased. This increase makes it necessary to improve the performance of a water pump as a motive power source for the coolant to flow, and leads to cost increase. However, in the present embodiment, as described later, the coolant flows in a short-side direction, of the entireties of the three power modules 2, which is a direction perpendicular to the first side surface 2c. Thus, increase in the fluid resistance can be suppressed.

<Cooler 4>

The cooler 4, which is a major part of the present disclosure, will be described. The cooler 4 cools the cooling plate 5, each power module 2, and the capacitor 3. As the coolant, for example, water or an ethylene glycol solution is used. The cooler 4 includes a flow path through which the coolant flows. The flow path is formed by the cooling flow path 4a, a first flow path hole 4b, a second flow path hole 4c, a first coupling portion 4d, and a second coupling portion 4e. The cooler 4 is formed by, for example, aluminum die casting.

The cooling flow path 4a is a flow path through which the coolant flows, along the other surface 5c of the cooling plate 5, from the first side surface 2c side of the power module 2 to the second side surface 2d side thereof. The cooling flow path 4a is a portion between the other surface 5c of the cooling plate 5 and a flow path surface 4a2 of the cooler 4. The first flow path hole 4b is a flow path disposed apart from the cooling flow path 4a so as to be closer to the opposite side to the power module 2 side than a portion of the cooling flow path 4a on the first side surface 2c side is, and extending from the third side surface 2e side of the power module 2 adjacent to the first side surface 2c to the fourth side surface 2f side thereof opposite to the third side surface 2e. The second flow path hole 4c is a flow path disposed apart from the cooling flow path 4a so as to be closer to the opposite side to the power module 2 side than a portion of the cooling flow path 4a on the second side surface 2d side is, and extending from the third side surface 2e side to the fourth side surface 2f side. The first coupling portion 4d is a flow path coupling the first flow path hole 4b and the portion of the cooling flow path 4a on the first side surface 2c side. The second coupling portion 4e is a flow path coupling the second flow path hole 4c and the portion of the cooling flow path 4a on the second side surface 2d side.

A coolant outlet/inlet through which the coolant flows out/in is provided at a portion of the first flow path hole 4b on the third side surface 2e side or the fourth side surface 2f side. A coolant outlet/inlet through which the coolant flows out/in is provided at a portion of the second flow path hole 4c on the third side surface 2e side or the fourth side surface 2f side. As shown in FIG. 5, pipes 9 are provided to the coolant outlet/inlet by, for example, press fitting. Seal bolts 11 close: an opening, of the first flow path hole 4b, which is located on the third side surface 2e side or the fourth side surface 2f side and to which the corresponding pipe 9 is not provided; and an opening, of the second flow path hole 4c, which is located on the third side surface 2e side or the fourth side surface 2f side and to which the corresponding pipe 9 is not provided. In the present embodiment, as shown in FIG. 3, a pipe 9 as an inlet for the coolant is provided at the portion of the first flow path hole 4b on the third side surface 2e side, and a pipe 9 as an outlet for the coolant is provided at the portion of the second flow path hole 4c on the third side surface 2e side. Meanwhile, the seal bolts 11 close: the opening, of the first flow path hole 4b, which is located on the fourth side surface 2f side; and the opening, of the second flow path hole 4c, which is located on the fourth side surface 2f side. Each coolant outlet/inlet can be disposed with the position thereof being arbitrarily selected from out of the third side surface 2e side or the fourth side surface 2f side. Thus, selection for the flow path can be made according to the position at which the power conversion device 1 is installed. Therefore, the degree of freedom in arrangement of the flow path can be increased. By providing the pipes 9, the coolant can be easily caused to flow into the cooler 4, and the coolant can be easily caused to flow out from the cooler 4. By providing the seal bolts 11, the flow path can be easily closed.

The first flow path hole 4b and the second flow path hole 4c cause the coolant to flow unidirectionally. Since the first flow path hole 4b causes the coolant to flow unidirectionally, the coolant can be caused to flow parallelly and evenly through the cooling fins 5a. Therefore, if a plurality of the power modules 2 are provided, the cooling capability is made uniform among the power modules 2, and the temperatures of the power modules 2 can be made equal to one another. Consequently, electrical characteristics of the power modules 2 having temperature characteristics become even among the power modules 2, and switching controllability of each power module 2 becomes favorable.

In the present embodiment, the first flow path hole 4b and the second flow path hole 4c are provided in the forms of through-holes, and one opening of each through-hole is closed by the corresponding seal bolt 11. However, the first flow path hole 4b and the second flow path hole 4c may be provided so as not to penetrate the cooler 4. If each flow path hole is provided so as not to penetrate the cooler 4, no seal bolt 11 is necessary, and thus the power conversion device 1 can be manufactured at low cost. Although the pipes 9 are formed as bodies separate from the cooler 4 in the present embodiment, the pipes 9 may be formed by die casting so as to be integrated with the cooler 4. If the pipes 9 are integrated with the cooler 4, no pipe 9 is necessary, and thus the power conversion device 1 can be manufactured at low cost.

The cross-sectional shapes, of one or both of the first flow path hole 4b and the second flow path hole 4c, that are perpendicular to the directions in which the first flow path hole 4b and the second flow path hole 4c extend, are circular shapes. In the present embodiment, as shown in FIG. 4, the cross-sectional shapes of both of the first flow path hole 4b and the second flow path hole 4c are circular shapes. If the cross-sectional shapes of one or both of the first flow path hole 4b and the second flow path hole 4c are circular shapes, each flow path hole is easily formed during manufacturing of the flow path hole, whereby productivity for the power conversion device 1 can be improved. If the cooler 4 is manufactured by die casting, productivity for the power conversion device 1 can be particularly improved. It is noted that the cross-sectional shape of each flow path hole is not limited to a circular shape and may be another shape such as a quadrangular shape.

The sizes of the cross-sectional shapes, of one or both of the first flow path hole 4b and the second flow path hole 4c, that are perpendicular to the directions in which the first flow path hole 4b and the second flow path hole 4c extend, may differ at portions between the third side surface side and the fourth side surface side. For example, as shown in FIG. 6, the first flow path hole 4b may be formed in a stepped shape in which the cross-sectional shape thereof at an intermediate portion (stepped portion 4b1) is made small. If the flow path hole is formed in a stepped shape in this manner, the position of the cooling flow path 4a can be lowered, and thus the size of the power conversion device 1 can be reduced. In addition, if the shape of at least a part of the flow path hole is changed to another shape such as a quadrangular shape, restrictions on arrangement of components and restrictions on arrangement of the flow path imposed by the flow path hole, can be alleviated. Thus, the degree of freedom in arrangement of the components can be improved. It is noted that the flow path hole may be formed in another manner, e.g., formed by tapering a flow path hole.

As shown in FIG. 4, the coolant flows in the flowing direction 10 through the first flow path hole 4b, the first coupling portion 4d, the cooling flow path 4a, the second coupling portion 4e, and the second flow path hole 4c in this order. The flowing direction 10 may be reverse to this direction. In the present embodiment, as shown in FIG. 3, the pipe 9 provided to the first flow path hole 4b serves as an inlet for the coolant, and the pipe 9 provided to the second flow path hole 4c serves as an outlet for the coolant. However, the present disclosure is not limited thereto. The inlet and the outlet may be reversed, and the coolant outlet/inlets may be provided on the fourth side surface 2f side. If the capacitor 3 is disposed on the first side surface 2c side of the power module 2 as shown in FIG. 2 and the coolant flows into the first flow path hole 4b, the capacitor 3 can be cooled with the coolant which is flowing in at low temperature. Thus, the thermally weak capacitor 3 can be efficiently protected.

The power module 2 and each of at least a part of the first flow path hole 4b and at least a part of the second flow path hole 4c are located to overlap with each other as seen in a direction perpendicular to the one surface 5b of the cooling plate 5. With such a configuration, since the power module 2 and each of at least a part of the first flow path hole 4b and at least a part of the second flow path hole 4c are located to overlap with each other, the projection area of the cooler 4 can be reduced without reducing the area for cooling the power module 2, as compared to the case where each flow path hole which is a unidirectional flow portion and the cooling flow path 4a are on the same plane. Since the projection area of the cooler 4 can be reduced, the size of the power conversion device 1 can be reduced. In addition, since the power module 2, the cooler 4, and the capacitor 3 are separate bodies and the power module 2 is disposed on the cooling plate 5, the degree of freedom in arrangement of the power module 2, the cooler 4, and the capacitor 3 is high, and this arrangement does not influence the degree of freedom in arrangement of other components. Therefore, the scope of deliberation regarding size reduction of the power conversion device 1 is broadened, and the size of the power conversion device 1 can be easily reduced. In addition, since the configuration and the shape of the flow path of the cooler 4 are simple, the degree of freedom in arrangement of the flow path of the cooler 4 is high, and the position of each coolant outlet/inlet can be easily changed. Since the configuration and the shape of the flow path of the cooler 4 are simple, cost for the power conversion device 1 can be reduced.

The length on the first side surface 2c side obtained by summing the lengths in the long-side direction of the first side surfaces 2c of the three power modules 2 is longer than the length of each power module 2 on the third side surface 2e side, and the coolant flows from the first side surface 2c side to the second side surface 2d side through the cooling flow path 4a. Thus, the coolant flows in the short-side direction of the entireties of the power modules 2 through the cooling flow path 4a. Since the coolant flows in the short-side direction of each power module 2, the flow path can be shortened, and increase in the fluid resistance can be suppressed. Since increase in the fluid resistance is suppressed, the pitch between the cooling fins 5a can be narrowed to increase the occupation rate of the cooling fins 5a. If the occupation rate of the cooling fins 5a is increased, heat dissipation from the power module 2 can be improved.

In the present embodiment, as shown in FIG. 2, the cooling fins 5a are provided only at a portion, of the other surface 5c of the cooling plate 5, that opposes the flow path surface 4a2 and that is opposite to the side on which the power module 2 is disposed. The arrangement of the cooling fins 5a is not limited thereto, and cooling fins 5a may further be disposed at a portion, of the other surface 5c of the cooling plate 5, that opposes the first coupling portion 4d. If the cooling fins 5a are further disposed, the coolant can be caused to impact the added cooling fins 5a perpendicularly thereto. If the coolant is caused to impact the cooling fins 5a perpendicularly thereto, cooling capability can be improved owing to a jet caused by the impact. The improvement in the cooling capability makes it possible to reduce the chip size of each power semiconductor and thus makes it possible to reduce the size of the power conversion device 1.

<Manufacturing Method for Power Conversion Device 1>

A manufacturing method for the power conversion device 1 will be described with reference to FIG. 7. Since the major part of the present disclosure is the structure of the cooler 4, description will be given focusing on a manufacturing method for the cooler 4. The manufacturing method for the power conversion device 1 includes a member preparation step (S11), a cooler manufacturing step (S12), and a cooling flow path formation step (513).

The member preparation step is a step of preparing: each power module 2 including the power semiconductor and formed in the shape of a rectangular parallelepiped having the bottom surface 2a, the top surface 2b, and the four side surfaces (the first side surface 2c, the second side surface 2d, the third side surface 2e, and the fourth side surface 2f); and the flat-shaped cooling plate 5. If the cooling plate 5 includes a plurality of the cooling fins 5a, the plurality of the cooling fins 5a protruding in a direction away from the other surface 5c are formed on the cooling plate 5 with the intervals between the cooling fins 5a being narrowed by forging in the member preparation step. The manufacturing method for the cooling fins 5a is not limited thereto, and the cooling fins 5a may be manufactured by cutting or the like. However, if the cooling fins 5a are manufactured by forging, the cooling fins 5a having a narrow pitch can be formed with the intervals between the plurality of the cooling fins 5a being narrowed. If the cooling fins 5a having a narrow pitch are formed, high cooling capability for the power module 2 can be ensured. The cooling fins 5a are made so as to have, for example, widths of 1.5 mm and a pitch of 2.5 mm.

The cooler manufacturing step is a step of manufacturing the cooler 4. The cooler 4 includes, in an assembled state, the cooling flow path 4a, the first flow path hole 4b, the second flow path hole 4c, the first coupling portion 4d, and the second coupling portion 4e. In the assembled state, the power module 2 and each of at least a part of the first flow path hole 4b and at least a part of the second flow path hole 4c are located to overlap with each other as seen in the direction perpendicular to the one surface 5b of the cooling plate 5. The cooler 4 is manufactured by die casting. The material of the cooler 4 is, for example, aluminum. The first flow path hole 4b and the second flow path hole 4c are each formed by using a pull-out core. A portion constituting the cooling flow path 4a, the first coupling portion 4d, and the second coupling portion 4e are formed by using a fixed mold or a movable mold. The pull-out cores and the fixed mold or the movable mold for die casting, make it possible to easily form the portion constituting the flow path of the cooler 4. Since complex machining and the like are not necessary to form the portion constituting the flow path, the power conversion device 1 can be manufactured at low cost. Since the configuration and the shape of the flow path are simple, the degree of freedom in arrangement of the flow path of the cooler 4 can be increased. It is noted that, if the first flow path hole 4b and the second flow path hole 4c are provided in the forms of through-holes, the seal bolt 11 is provided to one opening of each of the first flow path hole 4b and the second flow path hole 4c, whereby the seal bolt 11 closes the opening.

Each of the first flow path hole 4b and the second flow path hole 4c may be formed by abutting pull-out cores from both of the third side surface 2e side and the fourth side surface 2f side. If each of the first flow path hole 4b and the second flow path hole 4c is formed by abutting the pull-out cores, the length of each pull-out core can be reduced as compared to the case where the flow path hole is formed by using a pull-out core from one side. Since the length of each pull-out core can be reduced, manufacturability by die casting can be improved. In addition, reduction in the cross-sectional area of each flow path hole due to a draft of the pull-out core can be alleviated as compared to the case where the flow path hole is formed by using a pull-out core from one side.

The cooling flow path formation step is a step of thermally connecting the bottom surface 2a of the power module 2 and the one surface 5b of the cooling plate 5 and joining the other surface 5c of the cooling plate 5 to the outer peripheral portion 4al of the cooling flow path 4a. The joining between the other surface 5c of the cooling plate 5 and the outer peripheral portion 4al of the cooling flow path 4a is performed by metal joining (for example, friction stir welding). The method for the joining is not limited to metal joining, and the joining may be performed by screwing or the like. If these are joined by metal joining, restrictions on ensuring of an insulation distance and on arrangement of components can be alleviated as compared to a configuration obtained by screwing. If the cooling plate 5 is joined to the portion constituting the flow path manufactured by die casting, the flow path for the coolant can be formed. Thus, the flow path can be easily formed at low cost. Since the power module 2 is mounted to the cooler 4 with the cooling plate 5 having a high degree of freedom against manufacturing restrictions and interposed therebetween without directly mounting the power module 2 to the cooler 4, the degree of freedom regarding the shapes of the cooling fins 5a provided on the cooling plate 5 is high. Therefore, high cooling capability for the power module 2 can be easily ensured at low cost.

As described above, in the power conversion device 1 according to the first embodiment, the power module 2 and each of at least a part of the first flow path hole 4b and at least a part of the second flow path hole 4c are located to overlap with each other as seen in the direction perpendicular to the one surface 5b of the cooling plate 5. Thus, the projection area of the cooler 4 can be reduced without reducing the area for cooling the power module 2. Since the projection area of the cooler 4 can be reduced, the size of the power conversion device 1 can be reduced. In addition, since the power module 2 is disposed on the cooling plate 5, the degree of freedom in arrangement of the power module 2 and the cooler 4 is high, and this arrangement does not influence the degree of freedom in arrangement of other components. Therefore, the scope of deliberation regarding size reduction of the power conversion device 1 is broadened, and the size of the power conversion device 1 can be easily reduced. In addition, since the configuration and the shape of the flow path of the cooler 4 are simple, the degree of freedom in arrangement of the flow path of the cooler 4 can be increased, and the position of each coolant outlet/inlet can be easily changed. If the plurality of power modules 2 are disposed side by side in a direction parallel to each first side surface 2c and the length on the first side surface 2c side obtained by summing the lengths in the long-side direction of the first side surfaces 2c of the power modules 2 is longer than the length of each power module 2 on the third side surface 2e side, the coolant flows in the short-side direction of the entireties of the power modules 2 through the cooling flow path 4a since the coolant flows from the first side surface 2c side to the second side surface 2d side through the cooling flow path 4a. Therefore, the flow path is shortened, and increase in the fluid resistance can be suppressed.

If the cooling plate 5 includes the cooling fins 5a, each power module 2 can be efficiently cooled. In addition, if the cross-sectional shapes, of one or both of the first flow path hole 4b and the second flow path hole 4c, that are perpendicular to the directions in which the first flow path hole 4b and the second flow path hole 4c extend, are circular shapes, each flow path hole is easily formed during manufacturing of the flow path hole, whereby productivity for the power conversion device 1 can be improved. In addition, if the sizes of the cross-sectional shapes, of one or both of the first flow path hole 4b and the second flow path hole 4c, that are perpendicular to the directions in which the first flow path hole 4b and the second flow path hole 4c extend, differ at portions between the third side surface side and the fourth side surface side, e.g., if a portion of the first flow path hole 4b is formed in a stepped shape, the position of the cooling flow path 4a can be lowered, whereby the size of the power conversion device 1 can be reduced.

If the control board 8 is disposed to oppose each power module 2 and the capacitor 3, the size of the power conversion device 1 can be reduced, and reduction in the inductance of the power conversion device 1 can be realized. In addition, if the power terminals 2g of the power module 2 and the power terminal 3g of the capacitor 3 are electrically connected between the control board 8 and each of the power module 2 and the capacitor 3, the electrical wiring between the power module 2 and the capacitor 3 can be made shortest, and reduction in the inductance of the power conversion device 1 can be realized. In addition, if the interval between the outer wall member 20 and the bottom surface 3a of the capacitor 3 is filled with the heat-dissipating resin 7, the use amount of the heat-dissipating resin 7 is reduced to reduce cost therefor, and the capacitor 3 can be efficiently cooled. In addition, if the gaps between the outer wall member 20 and the side surfaces of the capacitor 3 are filled with the heat-dissipating resin 7, the capacitor 3 can be efficiently cooled. In addition, if the capacitor 3 is disposed on the first side surface 2c side of the power module 2 and the coolant flows into the first flow path hole 4b, the capacitor 3 can be cooled with the coolant which is flowing in at low temperature. Thus, the thermally weak capacitor 3 can be efficiently protected.

If a coolant outlet/inlet through which the coolant flows out/in is provided at a portion of the first flow path hole 4b on the third side surface 2e side or the fourth side surface 2f side and a coolant outlet/inlet through which the coolant flows out/in is provided at a portion of the second flow path hole 4c on the third side surface 2e side or the fourth side surface 2f side, each coolant outlet/inlet can be disposed with the position thereof being arbitrarily selected from out of the third side surface 2e side or the fourth side surface 2f side. Thus, selection for the flow path can be made according to the position at which the power conversion device 1 is installed. Therefore, the degree of freedom in arrangement of the flow path can be increased. In addition, if the pipes 9 are provided to the coolant outlet/inlets, the coolant can be easily caused to flow into, and flow out from, the cooler 4. In addition, if the seal bolts 11 close the opening, of the first flow path hole 4b, which is located on the third side surface 2e side or the fourth side surface 2f side and the opening, of the second flow path hole 4c, which is located on the third side surface 2e side or the fourth side surface 2f side, the flow path can be easily closed.

If the first flow path hole 4b and the second flow path hole 4c are formed by using pull-out cores by die casting and the portion constituting the cooling flow path 4a, the first coupling portion 4d, and the second coupling portion 4e are formed by using a fixed mold or a movable mold by die casting, the portion constituting the flow path of the cooler 4 can be easily formed. Since complex machining and the like are not necessary to form the portion constituting the flow path, the power conversion device 1 can be manufactured at low cost. Since the configuration and the shape of the flow path are simple, the degree of freedom in arrangement of the flow path of the cooler 4 can be increased. In addition, if the plurality of the cooling fins 5a protruding in a direction away from the other surface 5c are formed on the cooling plate 5 with the intervals between the cooling fins 5a being narrowed by forging, high cooling capability for the power module 2 can be ensured. In addition, if the other surface 5c of the cooling plate 5 and the outer peripheral portion 4al of the cooling flow path 4a are joined by metal joining, restrictions on ensuring of an insulation distance and on arrangement of components can be alleviated as compared to a configuration obtained by screwing.

### Second Embodiment

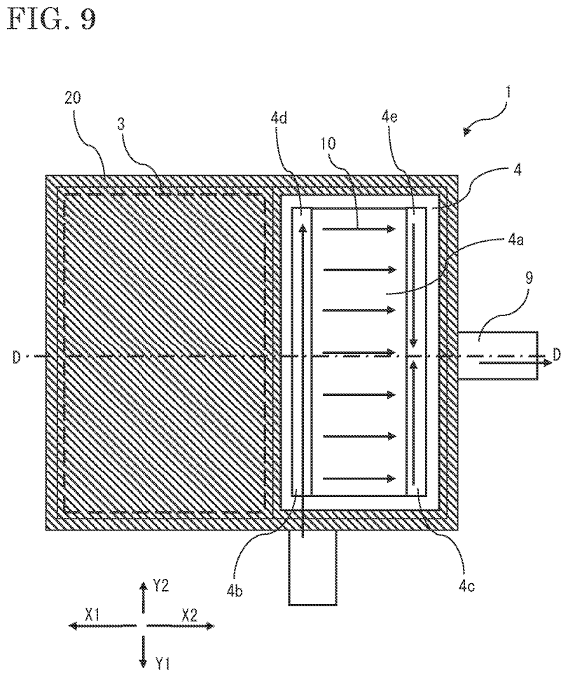

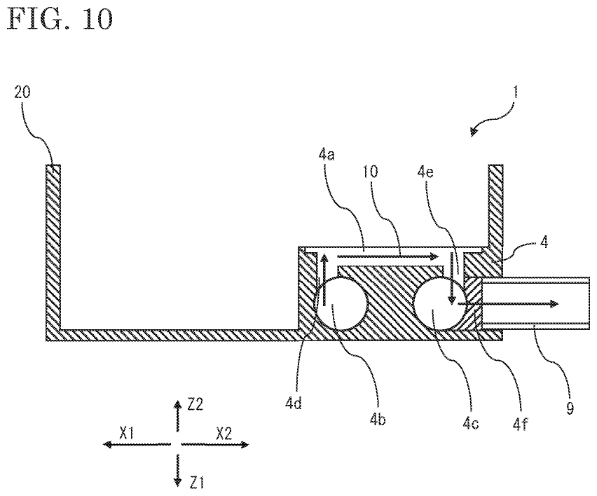

A power conversion device 1 according to a second embodiment will be described. FIG. 9 is a plan view of the power conversion device 1 according to the second embodiment and shows the cooler 4 and the outer wall member 20 while excluding the internal components. FIG. 10 is a cross-sectional view of the power conversion device 1 taken at the cross-sectional position D-D in FIG. 9. Neither of the drawings show any power modules 2, but in actuality, the power modules 2 are disposed at the same positions as those in the first embodiment. The power conversion device 1 according to the second embodiment includes a third flow path hole 4f in addition to the components of the power conversion device 1 described in the first embodiment.

The cooler 4 includes the third flow path hole 4f coupled to the second flow path hole 4c and extending from the second flow path hole 4c to the second side surface 2d side (the side indicated by the arrow X2) or an opposite side to the cooling flow path 4a (the side indicated by the arrow Z1). A coolant outlet/inlet through which the coolant flows out/in is provided at a portion of the first flow path hole 4b on the third side surface 2e side (the side indicated by the arrow Y1) or the fourth side surface 2f side (the side indicated by the arrow Y2). A coolant outlet/inlet through which the coolant flows out/in is provided at a portion of the third flow path hole 4f on an opposite side to the second flow path hole 4c side. In the present embodiment, the portion of the first flow path hole 4b on the third side surface 2e side (the side indicated by the arrow Y1), is a coolant outlet/inlet, and a pipe 9 is provided to the coolant outlet/inlet. The third flow path hole 4f extends to the second side surface 2d side (the side indicated by the arrow X2). The portion of the third flow path hole 4f on the second side surface 2d side, i.e., the opposite side to the second flow path hole 4c side, is a coolant outlet/inlet, and a pipe 9 is provided to the coolant outlet/inlet. Although an example in which the pipes 9 are provided to the coolant outlet/inlets has been described here, an air valve for releasing air from inside the flow path through which the coolant flows may be provided. The coolant flows into the first flow path hole 4b, and the coolant flows in the flowing direction 10 through the inside of the flow path. The flowing direction 10 may be reverse to this direction.

The present embodiment has a configuration in which the capacitor 3 (indicated by the broken line in FIG. 9) is disposed on the first side surface 2c side (the side indicated by the arrow X1) of the power module 2. Thus, the third flow path hole 4f is provided to the second flow path hole 4c. If the capacitor 3 is disposed on the second side surface 2d side (the side indicated by the arrow X2) of the power module 2, the third flow path hole 4f may be provided to the first flow path hole 4b.

As described above, the power conversion device 1 according to the second embodiment includes the third flow path hole 4f extending from the second flow path hole 4c to the second side surface 2d side or the opposite side to the cooling flow path 4a. Thus, for the third flow path hole 4f, the coolant outlet/inlet through which the coolant flows out/in is provided on a side different from the third side surface 2e side or the fourth side surface 2f side. Therefore, the degree of freedom in arrangement of the flow path of the cooler 4 can be increased. Since the degree of freedom in arrangement of the flow path of the cooler 4 is increased, the position of the coolant outlet/inlet can be easily changed, and the number of steps for designing can be reduced. If an air valve is mounted to each coolant outlet/inlet, air in the flow path for the coolant can be eliminated. Thus, it is possible to suppress reduction in cooling performance, vibrations, and impact which could be caused by uneven flow of the coolant due to air in the flow path. In addition, it is possible to prevent defects such as damage to the flow path.

### Third Embodiment

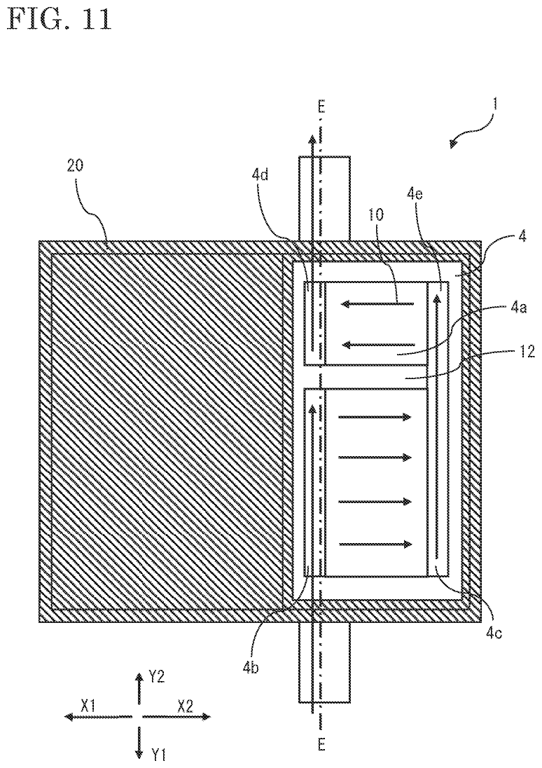

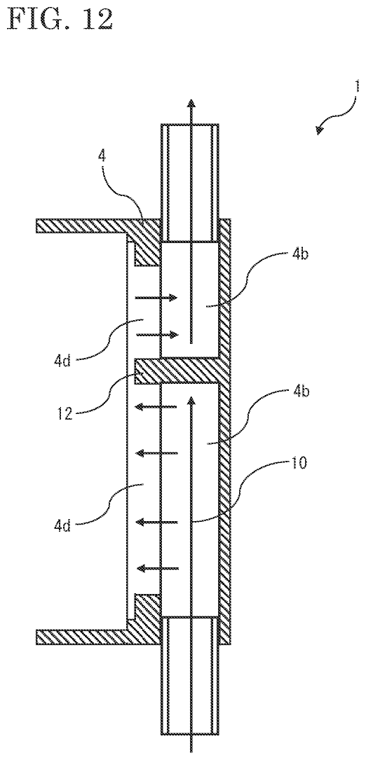

A power conversion device 1 according to a third embodiment will be described. FIG. 11 is a plan view of the power conversion device 1 according to the third embodiment and shows the cooler 4 and the outer wall member 20 while excluding the internal components. FIG. 12 is a cross-sectional view of the power conversion device 1 taken at the cross-sectional position E-E in FIG. 11. Neither of the drawings show any power modules 2, but in actuality, the power modules 2 are disposed at the same positions as those in the first embodiment. The power conversion device 1 according to the third embodiment includes a partition portion 12 for partitioning the flow path, in addition to the components of the power conversion device 1 described in the first embodiment.

Each of the first flow path hole 4b and the first coupling portion 4d is partitioned at a position thereof between the third side surface 2e side (the side indicated by the arrow Y1) and the fourth side surface 2f side (the side indicated by the arrow Y2). The cooling flow path 4a is partitioned at a position thereof, between the third side surface 2e side (the side indicated by the arrow Y1) and the fourth side surface 2f side (the side indicated by the arrow Y2), that corresponds to the position at which each of the first flow path hole 4b and the first coupling portion 4d is partitioned. The portion partitioning the first flow path hole 4b, the first coupling portion 4d, and the cooling flow path 4a is the partition portion 12. A coolant outlet/inlet through which the coolant flows out/in is provided at each of the portions of the first flow path hole 4b on the third side surface 2e side (the side indicated by the arrow Y1) and the fourth side surface 2f side (the side indicated by the arrow Y2). The portions of the second flow path hole 4c on the third side surface 2e side (the side indicated by the arrow Y1) and the fourth side surface 2f side (the side indicated by the arrow Y2) are closed by, for example, seal bolts 11.

The coolant flows into the first flow path hole 4b, and the coolant flows in the flowing direction 10 through the inside of the flow path. Since the partition portion 12 is provided, the coolant flows, as shown in FIG. 11, through the first flow path hole 4b, the first coupling portion 4d, the cooling flow path 4a, the second coupling portion 4e, the second flow path hole 4c, the second coupling portion 4e, the cooling flow path 4a, the first coupling portion 4d, and the first flow path hole 4b in this order. The cooling flow path 4a is partitioned into two portions by the partition portion 12, and the coolant flows in directions that are opposite between the said portions. As shown in FIG. 12, the first coupling portion 4d is partitioned into two portions by the partition portion 12, and the coolant flows in directions that are opposite between the said portions.

As described above, in the power conversion device 1 according to the third embodiment, each of the first flow path hole 4b and the first coupling portion 4d is partitioned at a position thereof between the third side surface 2e side and the fourth side surface 2f side, and the cooling flow path 4a is partitioned at a position thereof, between the third side surface 2e side and the fourth side surface 2f side, that corresponds to the position at which each of the first flow path hole 4b and the first coupling portion 4d is partitioned. Thus, since the portion constituting the cooling flow path 4a for cooling the power module 2 is divided, the cooling capability for the power module 2 and pressure loss in the flow path for the coolant can be easily adjusted.

### Fourth Embodiment

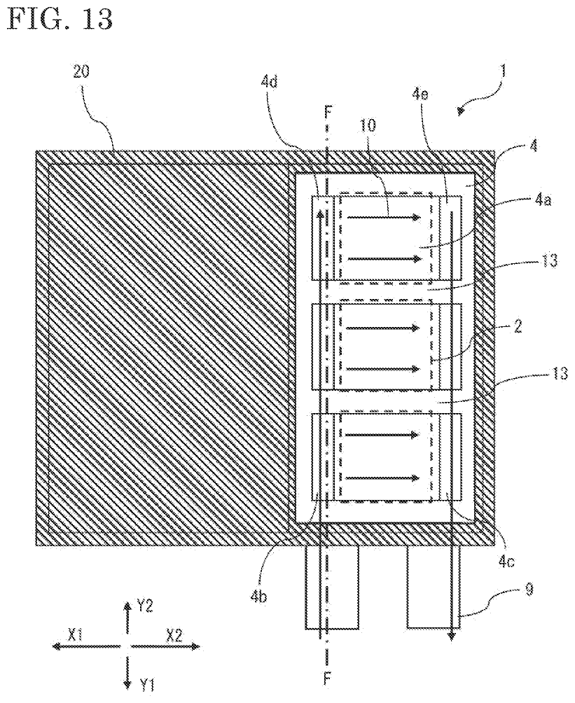

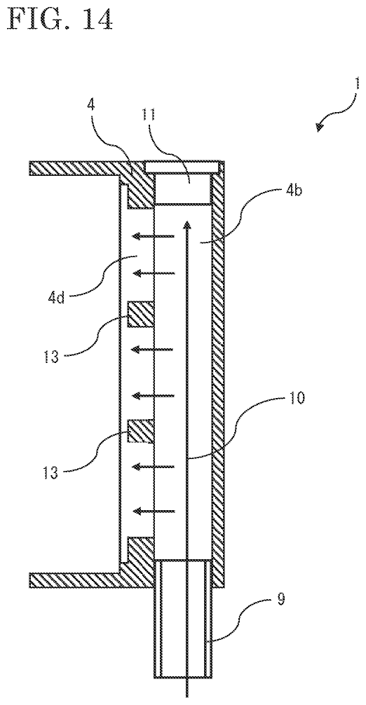

A power conversion device 1 according to a fourth embodiment will be described. FIG. 13 is a plan view of the power conversion device 1 according to the fourth embodiment and shows the cooler 4 and the outer wall member 20 while excluding the internal components. FIG. 14 is a cross-sectional view of the power conversion device 1 taken at the cross-sectional position F-F in FIG. 13. Neither of the drawings show any power modules 2, but in actuality, the power modules 2 are disposed at the same positions as those in the first embodiment. The power conversion device 1 according to the fourth embodiment includes partition portions 13 for partitioning the flow path, in addition to the components of the power conversion device 1 described in the first embodiment.

Each of the cooling flow path 4a, the first coupling portion 4d, and the second coupling portion 4e is partitioned at a plurality of positions thereof between the third side surface 2e side (the side indicated by the arrow Y1) and the fourth side surface 2f side (the side indicated by the arrow Y2), along a direction in which the coolant flows. The portions partitioning each of the cooling flow path 4a, the first coupling portion 4d, and the second coupling portion 4e are the partition portions 13. A coolant outlet/inlet through which the coolant flows out/in is provided at the portion of the first flow path hole 4b on the third side surface 2e side (the side indicated by the arrow Y1) or the fourth side surface 2f side (the side indicated by the arrow Y2). A coolant outlet/inlet through which the coolant flows out/in is provided at the portion of the second flow path hole 4c on the third side surface 2e side (the side indicated by the arrow Y1) or the fourth side surface 2f side (the side indicated by the arrow Y2). In the present embodiment, as shown in FIG. 13, the pipe 9 as an inlet for the coolant is provided at the portion of the first flow path hole 4b on the third side surface 2e side (the side indicated by the arrow Y1), and the pipe 9 as an outlet for the coolant is provided at the portion of the second flow path hole 4c on the third side surface 2e side (the side indicated by the arrow Y1). In addition, the seal bolts 11 close: the opening, of the first flow path hole 4b, which is located on the fourth side surface 2f side (the side indicated by the arrow Y2); and the opening, of the second flow path hole 4c, which is located on the fourth side surface 2f side (the side indicated by the arrow Y2).

The coolant flows into the first flow path hole 4b, and the coolant flows in the flowing direction 10 through the inside of the flow path. The cooling flow path 4a is partitioned into three portions by the partition portions 13. Since the partition portions 13 are provided, the coolant flows through the first flow path hole 4b, the first coupling portion 4d, the three cooling flow paths 4a, the second coupling portion 4e, and the second flow path hole 4c in this order. In the present embodiment, three power modules 2 (indicated by the broken lines in FIG. 13) are provided, and the three cooling flow paths 4a are formed correspondingly to the respective power modules 2. However, the configuration of the cooling flow paths 4a is not limited thereto. A configuration in which one cooling flow path 4a is provided for a plurality of the power modules 2, may be employed.

As described above, in the power conversion device 1 according to the fourth embodiment, each of the cooling flow path 4a, the first coupling portion 4d, and the second coupling portion 4e is partitioned at the plurality of positions thereof between the third side surface 2e side and the fourth side surface 2f side, along the direction in which the coolant flows. This partitioning causes the cooling flow path 4a to be divided correspondingly to the projection areas of the power modules 2. Thus, unnecessary portions of the cooling flow path 4a can be reduced. Since the unnecessary portions of the cooling flow path 4a can be reduced, the flow rate of the coolant in the cooling flow paths 4a can be increased, and cooling capability for each power module 2 can be improved. In addition, cooling fins 5a provided to the unnecessary portions of the cooling flow path 4a can be removed, and thus pressure loss in the cooling flow paths 4a can be reduced. Since pressure loss in the cooling flow paths 4a can be reduced, the cooling fins 5a can be provided with the pitch therebetween being narrowed correspondingly to the reduction in the pressure loss. By providing the cooling fins 5a with a narrower pitch, cooling capability for the power module 2 can be further improved. In addition, since the cooling fins 5a provided to the unnecessary portions of the cooling flow path 4a can be removed, cost for manufacturing the cooling plate 5 can be reduced.

### Fifth Embodiment

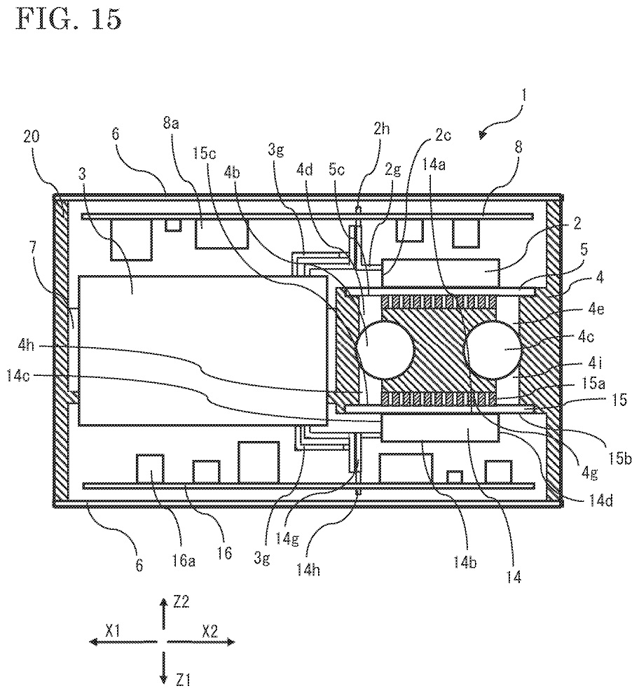

A power conversion device 1 according to a fifth embodiment will be described. FIG. 15 is a cross-sectional view of the power conversion device 1 and obtained by cutting the power conversion device 1 at the same position as the cross-sectional position A-A in FIG. 1. The power conversion device 1 according to the fifth embodiment includes opposing power modules 14 and the like in addition to the components of the power conversion device 1 described in the first embodiment.

The power conversion device 1 includes the opposing power modules 14, an opposing cooling plate 15, and an opposing control board 16. Each opposing power module 14 includes therein a power semiconductor and has the shape of a rectangular parallelepiped having a bottom surface 14a, a top surface 14b, and four side surfaces (a first side surface 14c, a second side surface 14d, a third side surface, and a fourth side surface). The third side surface and the fourth side surface are not shown in FIG. 15. The opposing power module 14 includes power terminals 14g and control terminals 14h exposed outward. The power terminals 14g are connected to the capacitor 3, and the control terminals 14h are connected to the opposing control board 16. The opposing cooling plate 15 has a flat shape, and one surface 15b thereof is thermally connected to the bottom surface 14a of the opposing power module 14. The other surface 5c of the cooling plate 5 and another surface 15c of the opposing cooling plate 15 are located to oppose each other with the cooler 4 interposed therebetween. The first side surface 2c side of each power module 2 and the first side surface 14c side of the corresponding opposing power module 14 are located on the same side. The opposing cooling plate 15 includes cooling fins 15a on the other surface 15c.

The opposing control board 16 outputs a signal for controlling an operation of each opposing power module 14, to control the operation of the opposing power module 14. The opposing control board 16 is mounted with a plurality of control components 16a, and the control terminals 14h are electrically connected to the opposing control board 16. The opposing control board 16 is disposed to oppose the opposing power module 14 and the capacitor 3. The power terminals 14g of the opposing power module 14 and the power terminal 3g of the capacitor 3 are electrically connected between the opposing control board 16 and each of the opposing power module 14 and the capacitor 3.

The cooler 4 further includes an opposing cooling flow path 4g, a third coupling portion 4h, and a fourth coupling portion 4i. The opposing cooling flow path 4g is a flow path through which the coolant flows, along the other surface 15c of the opposing cooling plate 15, from the first side surface 14c side of the opposing power module 14 to the second side surface 14d side thereof opposite to the first side surface 14c. The third coupling portion 4h is a flow path coupling the first flow path hole 4b and a portion of the opposing cooling flow path 4g on the first side surface 14c side (the side indicated by the arrow X1). The fourth coupling portion 4i is a flow path coupling the second flow path hole 4c and a portion of the opposing cooling flow path 4g on the second side surface 14d side (the side indicated by the arrow X2). The opposing power module 14 and each of at least a part of the first flow path hole 4b and at least a part of the second flow path hole 4c are located to overlap with each other as seen in a direction perpendicular to the other surface 15c of the opposing cooling plate 15. In FIG. 15, the power conversion device 1 includes lids 6 on both of the side indicated by the arrow 1i and the side indicated by the arrow Z2. Consequently, the cooler 4 can be manufactured in a state where both of the side indicated by the arrow Z1 and the side indicated by the arrow Z2 are opened. Thus, the pull-out cores and the fixed mold or the movable mold for die casting, make it possible to easily form the portion constituting the flow path in the same manner as in the manufacturing method described in the first embodiment.

As described above, in the power conversion device 1 according to the fifth embodiment, the other surface 5c of the cooling plate 5 and the other surface 15c of the opposing cooling plate 15 are located to oppose each other with the cooler 4 interposed therebetween, and the opposing power module 14 and each of at least a part of the first flow path hole 4b and at least a part of the second flow path hole 4c are located to overlap with each other as seen in the direction perpendicular to the other surface 15c of the opposing cooling plate 15. Thus, the projection area of the cooler 4 can be reduced without reducing the area for cooling the opposing power module 14. Since the projection area of the cooler 4 can be reduced, the size of the power conversion device 1 can be reduced. Since both of the power module 2 and the opposing power module 14 are disposed to overlap with each other with the cooler 4 interposed therebetween, the projection area of the power conversion device 1 can be reduced, whereby the size of the power conversion device 1 can be reduced.

### Sixth Embodiment

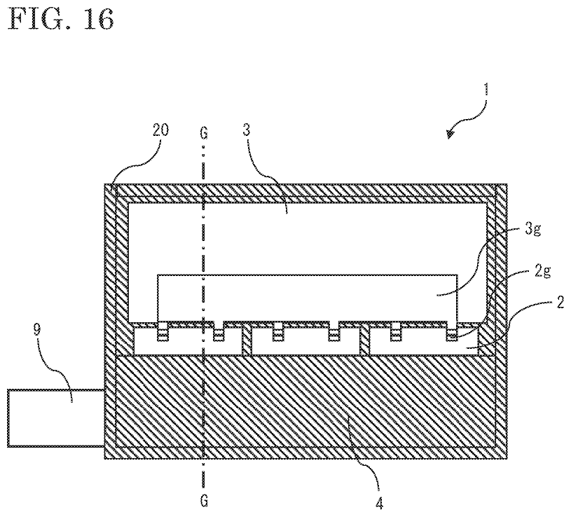

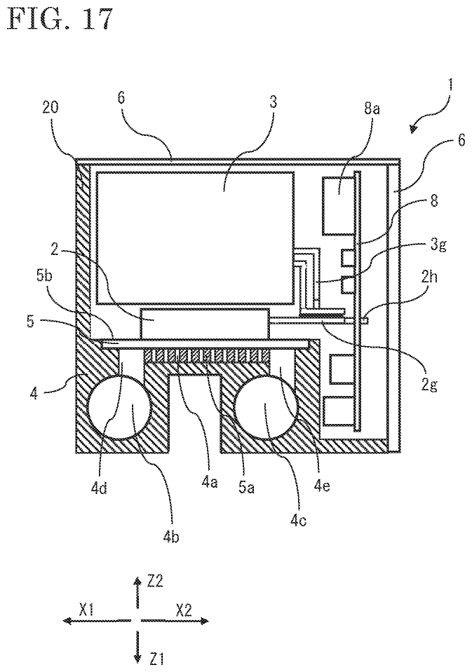

A power conversion device 1 according to a sixth embodiment will be described. FIG. 16 is a side view of the power conversion device 1 according to the sixth embodiment, excluding the lid 6 and the control board 8. FIG. 17 is a cross-sectional view of the power conversion device 1 taken at the cross-sectional position G-G in FIG. 16. The power conversion device 1 according to the sixth embodiment has a configuration in which the capacitor 3 is disposed at a position different from that in the first embodiment.

The capacitor 3 is disposed on the top surface 2b side (the side indicated by the arrow Z2) of each power module 2, and one surface in the long-side direction of the capacitor 3 opposes the top surface 2b side of the power module 2. The power module 2, the capacitor 3, and each of at least a part of the first flow path hole 4b and at least a part of the second flow path hole 4c, are located to overlap with each other as seen in the direction perpendicular to the one surface 5b of the cooling plate 5. The power conversion device 1 includes lids 6 on both of the side indicated by the arrow Z2 and the side indicated by the arrow X2 in FIG. 17. Consequently, the cooler 4 can be manufactured in a state where both of the side indicated by the arrow Z2 and the side indicated by the arrow X2 are opened. Thus, the pull-out cores and the fixed mold or the movable mold for die casting, make it possible to easily form the portion constituting the flow path in the same manner as in the manufacturing method described in the first embodiment.

As described above, in the power conversion device 1 according to the sixth embodiment, the power module 2, the capacitor 3, and each of at least a part of the first flow path hole 4b and at least a part of the second flow path hole 4c are located to overlap with each other as seen in the direction perpendicular to the one surface 5b of the cooling plate 5. Thus, the projection area of the power conversion device 1 can be reduced, whereby the size of the power conversion device 1 can be reduced. In addition, the capacitor 3 and the power module 2 can be disposed even closer to each other, and thus the electrical wiring between the power module 2 and the capacitor 3 can be made shorter, than in the above embodiments. Since the electrical wiring between the power module 2 and the capacitor 3 is shortened, reduction in the inductance of the power conversion device 1 can be realized. Since reduction in the inductance can be realized, the chip size of each power semiconductor is reduced, whereby cost for the power semiconductor can be reduced.

### Seventh Embodiment

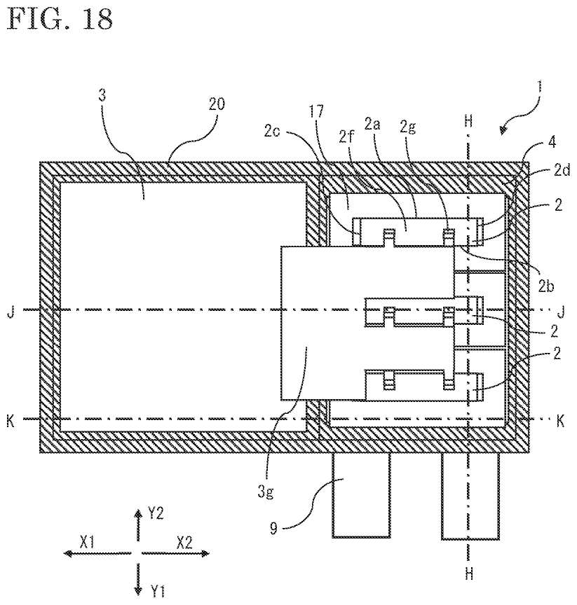

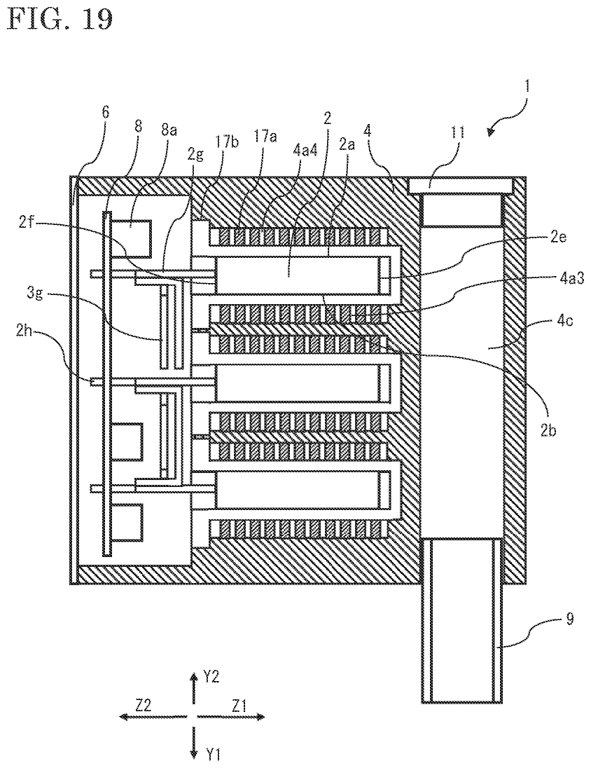

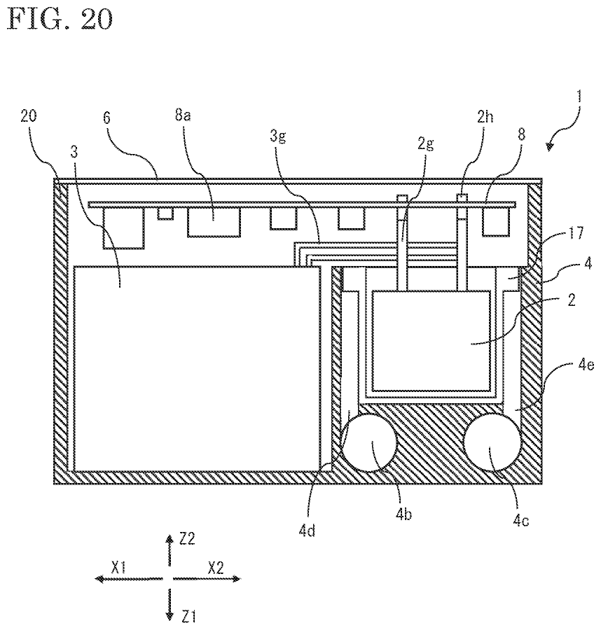

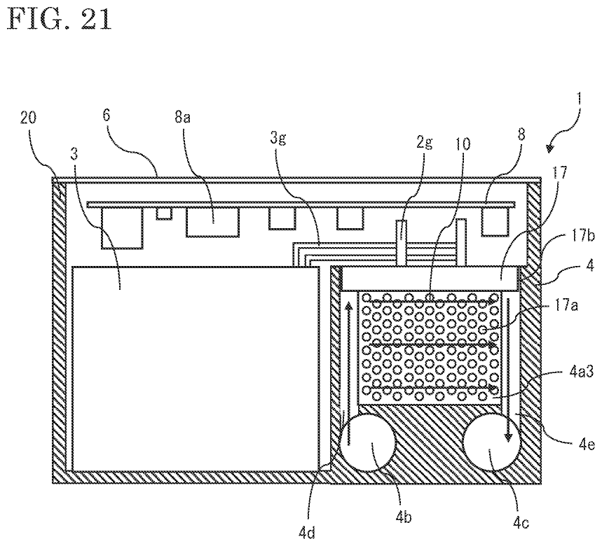

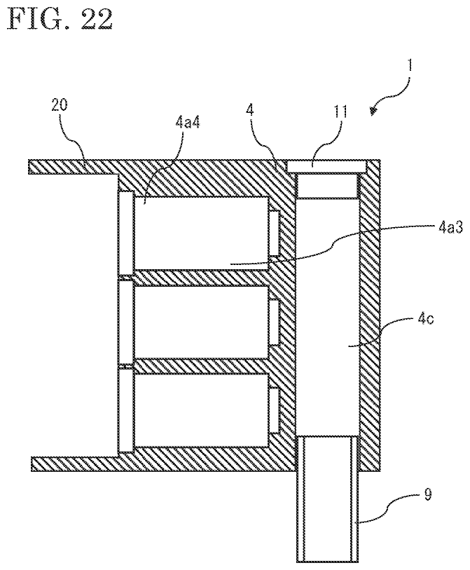

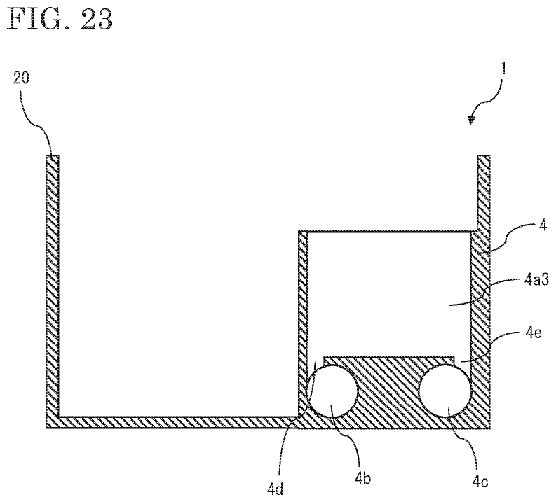

A power conversion device 1 according to a seventh embodiment will be described. FIG. 18 is a plan view of the power conversion device 1 according to the seventh embodiment, excluding the lid 6 and the control board 8. FIG. 19 is a cross-sectional view of the power conversion device 1 taken at the cross-sectional position H-H in FIG. 18. FIG. 20 is a cross-sectional view of the power conversion device 1 taken at the cross-sectional position J-J in FIG. 18. FIG. 21 is a cross-sectional view of the power conversion device 1 taken at the cross-sectional position K-K in FIG. 18. FIG. 22 is a cross-sectional view of the power conversion device 1 taken at the cross-sectional position H-H in FIG. 18 and shows the cooler 4 and the outer wall member 20 while excluding the internal components. FIG. 23 is a cross-sectional view of the power conversion device 1 taken at the cross-sectional position J-J in FIG. 18 and shows the cooler 4 and the outer wall member 20 while excluding the internal components. The power conversion device 1 according to the seventh embodiment has a configuration in which the power modules 2 are accommodated in cases 17 without providing any cooling plate.

The power conversion device 1 includes: the power modules 2; the cases 17 in which the power modules 2 are accommodated; the cooler 4 for cooling the cases 17; the capacitor 3; the control board 8; and the lid 6. Each power module 2 includes therein the power semiconductor (not shown) and has the shape of a rectangular parallelepiped having the bottom surface 2a, the top surface 2b, and the four side surfaces (the first side surface 2c, the second side surface 2d, the third side surface 2e, and the fourth side surface 2f). The power module 2 includes the power terminals 2g and the control terminals 2h on the fourth side surface 2f. The power modules 2 in the present embodiment are disposed as shown in FIG. 18. That is, the three power modules 2 are disposed side by side in a direction parallel to each first side surface 2c so as to have the same orientation. The capacitor 3 is disposed on the first side surface 2c side of each power module 2, and one surface in the long-side direction of the capacitor 3 opposes the first side surface 2c side of the power module 2. The first side surface 2c side refers to a side in a direction parallel to a normal direction to the side surface. That is, in FIG. 18, the first side surface 2c side refers to the side indicated by the arrow X1. Likewise, the second side surface 2d side refers to the side indicated by the arrow X2, the bottom surface 2a side refers to the side indicated by the arrow Y2, and the top surface 2b side refers to the side indicated by the arrow Y1. Further, in FIG. 19, the third side surface 2e side refers to the side indicated by the arrow Z1, and the fourth side surface 2f side refers to the side indicated by the arrow Z2.

The cases 17 have openings from which the power terminals 2g and the control terminals 2h are exposed outward. The power terminals 2g are connected to the power terminal 3g of the capacitor 3, and the control terminals 2h are connected to the control board 8. Each case 17 is made of a metal having a high thermal conductivity (for example, aluminum). Heat-dissipating resin (not shown) is injected into the gaps between the power modules 2 and the cases 17 so that the power modules 2 and the cases 17 are integrated with each other. Each case 17 includes a plurality of cooling fins 17a on the outer surface of a wall thereof opposing the top surface 2b of the corresponding power module 2 and on the outer surface of a wall thereof opposing the bottom surface 2a of the power module 2. Although a configuration in which the cooling fins 17a are not provided on the outer surfaces of the case 17 may be employed, provision of the cooling fins 17a makes it possible to efficiently cool the power module 2. Although a configuration in which the three power modules 2 are provided is described in the present embodiment, the number of the power modules 2 is not limited to three.

The cooler 4 includes: top-surface-side cooling flow paths 4a3; bottom-surface-side cooling flow paths 4a4; the first flow path hole 4b; the second flow path hole 4c; the first coupling portion 4d; and the second coupling portion 4e. Each top-surface-side cooling flow path 4a3 is a flow path through which the coolant flows, along the outer surface of the wall of the corresponding case 17 opposing the top surface 2b of the corresponding power module 2, from the first side surface 2c side of the power module 2 to the second side surface 2d side thereof opposite to the first side surface 2c. Each bottom-surface-side cooling flow path 4a4 is a flow path through which the coolant flows, along the outer surface of the wall of the corresponding case 17 opposing the bottom surface 2a of the corresponding power module 2, from the first side surface 2c side of the power module 2 to the second side surface 2d side thereof. The first flow path hole 4b is a flow path disposed apart from the top-surface-side cooling flow path 4a3 and the bottom-surface-side cooling flow path 4a4 so as to be closer to the third side surface 2e side adjacent to the first side surface 2c than portions of the top-surface-side cooling flow path 4a3 and the bottom-surface-side cooling flow path 4a4 on the first side surface 2c side are, and extending from the top surface 2b side to the bottom surface 2a side.

The second flow path hole 4c is a flow path disposed apart from the top-surface-side cooling flow path 4a3 and the bottom-surface-side cooling flow path 4a4 so as to be closer to the third side surface 2e side than portions of the top-surface-side cooling flow path 4a3 and the bottom-surface-side cooling flow path 4a4 on the second side surface 2d side are, and extending from the top surface 2b side to the bottom surface 2a side. The first coupling portion 4d is a flow path coupling the first flow path hole 4b and the portions of the top-surface-side cooling flow path 4a3 and the bottom-surface-side cooling flow path 4a4 on the first side surface 2c side. The second coupling portion 4e is a flow path coupling the second flow path hole 4c and the portions of the top-surface-side cooling flow path 4a3 and the bottom-surface-side cooling flow path 4a4 on the second side surface 2d side.

The coolant flows in the flowing direction 10 through the first flow path hole 4b, the first coupling portion 4d, the top-surface-side cooling flow path 4a3 or the bottom-surface-side cooling flow path 4a4, the second coupling portion 4e, and the second flow path hole 4c in this order. Each case 17 is in contact with the cooler 4 at a side surface 17b provided with a seal structure for the periphery of an opened portion, and a flow path through which the coolant flows is sealed. The seal structure is implemented by, for example, an O ring. The power module 2 and each of at least a part of the first flow path hole 4b and at least a part of the second flow path hole 4c are located to overlap with each other as seen in a direction perpendicular to the third side surface 2e of the power module 2. It is noted that the pull-out cores and the fixed mold or the movable mold for die casting, make it possible to easily form the portion constituting the flow path of the cooler 4 in the same manner as in the manufacturing method described in the first embodiment.

As described above, in the power conversion device 1 according to the seventh embodiment, the power module 2 and each of at least a part of the first flow path hole 4b and at least a part of the second flow path hole 4c are located to overlap with each other as seen in the direction perpendicular to the third side surface 2e of the power module 2. Thus, the projection area of the cooler 4 can be reduced. Since the projection area of the cooler 4 can be reduced, the size of the power conversion device 1 can be reduced. In addition, the cooler 4 includes the top-surface-side cooling flow paths 4a3 and the bottom-surface-side cooling flow paths 4a4, and thus each power module 2 can be cooled from both sides, whereby cooling capability for the power module 2 can be improved. Since cooling capability for the power module 2 is improved, a chip of each power semiconductor comes to have tolerance for heat. Thus, the chip size of the power semiconductor is reduced, whereby cost for the power semiconductor can be reduced. If each case 17 has the plurality of cooling fins 17a on the outer surface of the wall thereof opposing the top surface 2b of the corresponding power module 2 and on the outer surface of the wall thereof opposing the bottom surface 2a of the power module 2, the power module 2 can be efficiently cooled.

### Eighth Embodiment

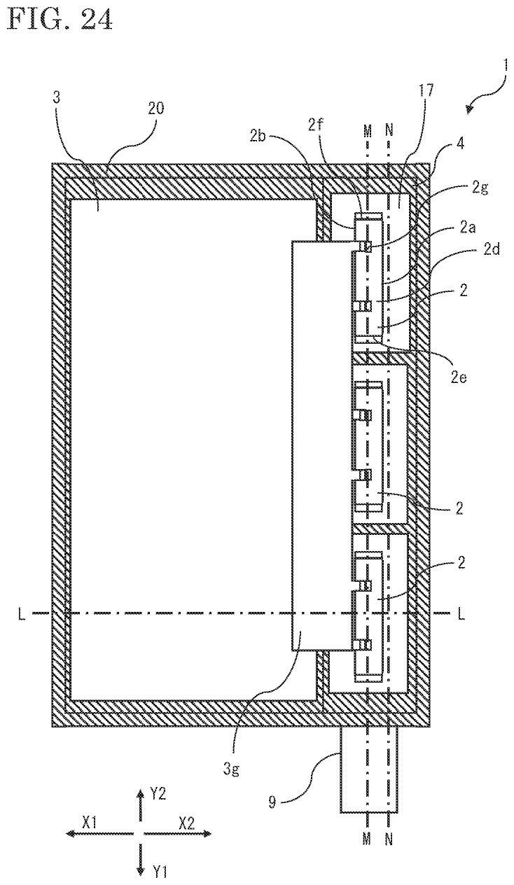

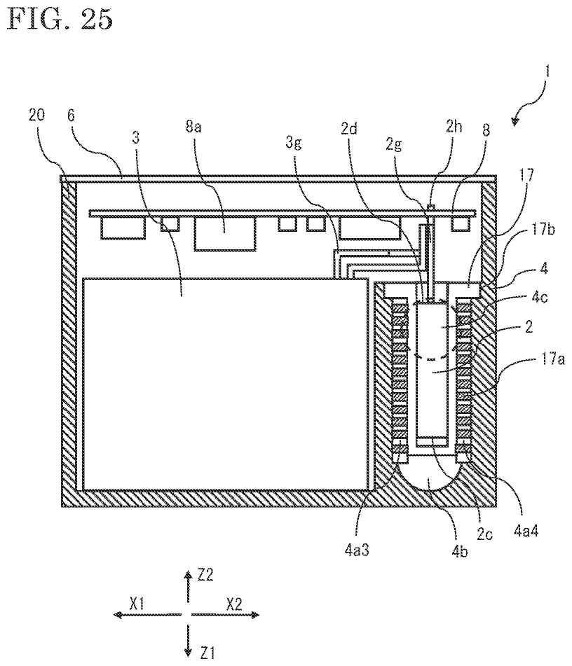

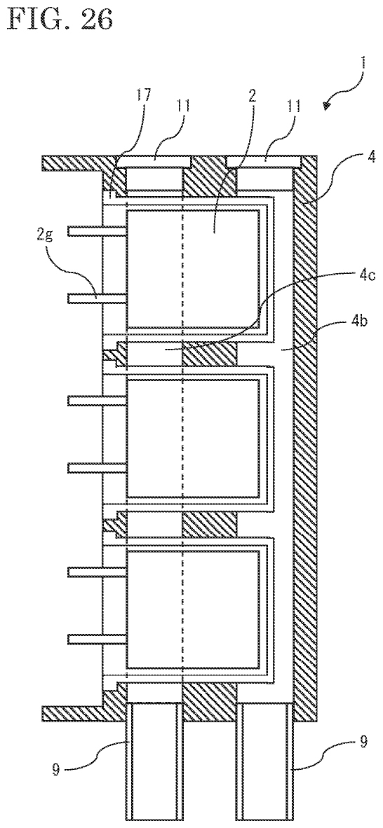

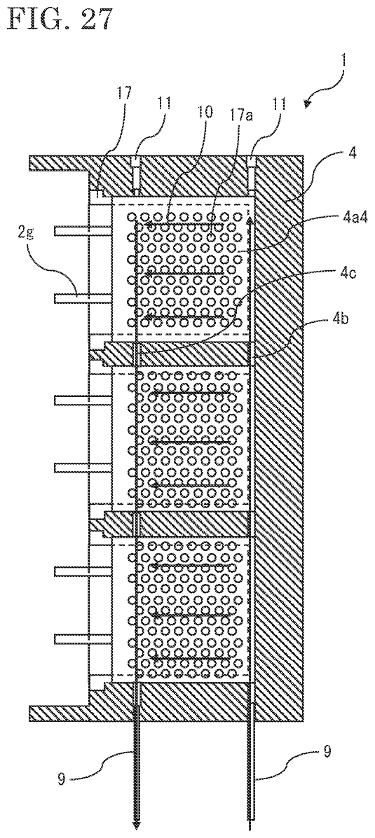

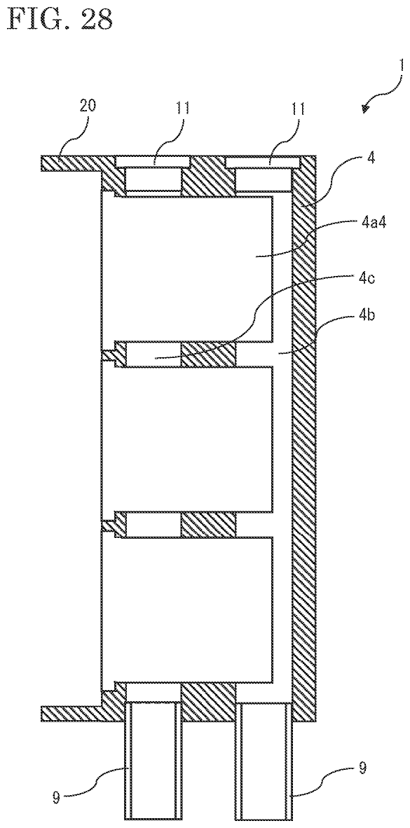

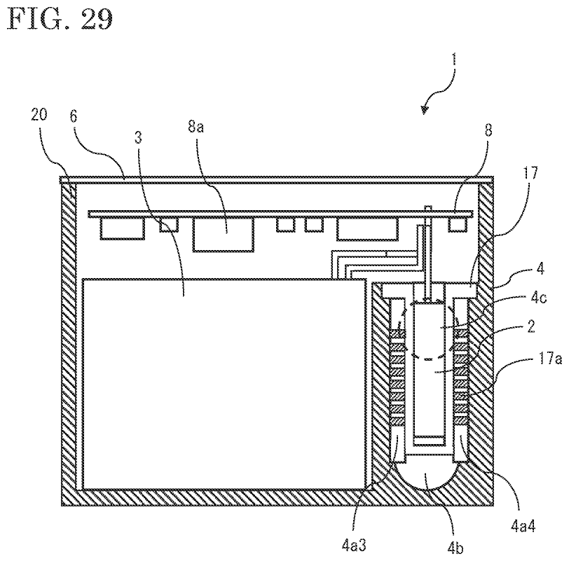

A power conversion device 1 according to an eighth embodiment will be described. FIG. 24 is a plan view of the power conversion device 1 according to the eighth embodiment, excluding the lid 6 and the control board 8. FIG. 25 is a cross-sectional view of the power conversion device 1 taken at the cross-sectional position L-L in FIG. 24. FIG. 26 is a cross-sectional view of the power conversion device 1 taken at the cross-sectional position M-M in FIG. 24. FIG. 27 is a cross-sectional view of the power conversion device 1 taken at the cross-sectional position N-N in FIG. 24. FIG. 28 is a cross-sectional view of the power conversion device taken at the cross-sectional position M-M in FIG. 24 and shows the cooler 4 and the outer wall member 20 while excluding the internal components. FIG. 29 is a cross-sectional view of another power conversion device 1 taken at the cross-sectional position L-L in FIG. 24. The power conversion device 1 according to the eighth embodiment has a configuration in which the power modules 2 accommodated in the cases 17 are disposed in a manner different from the manner in the seventh embodiment.

The power conversion device 1 includes: the power modules 2; the cases 17 in which the power modules 2 are accommodated; the cooler 4 for cooling the cases 17; the capacitor 3; the control board 8; and the lid 6. Each power module 2 includes therein the power semiconductor (not shown) and has the shape of a rectangular parallelepiped having the bottom surface 2a, the top surface 2b, and the four side surfaces (the first side surface 2c, the second side surface 2d, the third side surface 2e, and the fourth side surface 2f). The power module 2 includes the power terminals 2g and the control terminals 2h on the second side surface 2d. The power modules 2 in the present embodiment are disposed as shown in FIG. 24. That is, the three power modules 2 are disposed side by side in a direction parallel to each top surface 2b so as to have the same orientation. The capacitor 3 is disposed on the top surface 2b side of each power module 2, and one surface in the long-side direction of the capacitor 3 opposes the top surface 2b side of the power module 2. The top surface 2b side refers to a side in a direction parallel to a normal direction to the top surface. That is, in FIG. 23, the top surface 2b side refers to the side indicated by the arrow X1. Likewise, the bottom surface 2a side refers to the side indicated by the arrow X2, the third side surface 2e side refers to the side indicated by the arrow Y1, and the fourth side surface 2f side refers to the side indicated by the arrow Y2. Further, in FIG. 24, the first side surface 2c side refers to the side indicated by the arrow Z1, and the second side surface 2d side refers to the side indicated by the arrow Z2.

The cases 17 have openings from which the power terminals 2g and the control terminals 2h are exposed outward. The power terminals 2g are connected to the power terminal 3g of the capacitor 3, and the control terminals 2h are connected to the control board 8. Each case 17 includes the plurality of cooling fins 17a on the outer surface of the wall thereof opposing the top surface 2b of the corresponding power module 2 and on the outer surface of the wall thereof opposing the bottom surface 2a of the power module 2. Although a configuration in which the cooling fins 17a are not provided on the outer surfaces of the case 17 may be employed, provision of the cooling fins 17a makes it possible to efficiently cool the power module 2. Although a configuration in which the three power modules 2 are provided is described in the present embodiment, the number of the power modules 2 is not limited to three.

The cooler 4 includes: the top-surface-side cooling flow paths 4a3; the bottom-surface-side cooling flow paths 4a4; the first flow path hole 4b; and the second flow path hole 4c. Each top-surface-side cooling flow path 4a3 is a flow path through which the coolant flows, along the outer surface of the wall of the corresponding case 17 opposing the top surface 2b of the corresponding power module 2, from the first side surface 2c side of the power module 2 to the second side surface 2d side thereof opposite to the first side surface 2c. Each bottom-surface-side cooling flow path 4a4 is a flow path through which the coolant flows, along the outer surface of the wall of the corresponding case 17 opposing the bottom surface 2a of the corresponding power module 2, from the first side surface 2c side of the power module 2 to the second side surface 2d side thereof. The first flow path hole 4b is a flow path disposed at a portion of the case 17 on the first side surface 2c side, the flow path extending from the third side surface 2e side adjacent to the first side surface 2c to the fourth side surface 2f side opposite to the third side surface 2e so as to be connected to the top-surface-side cooling flow path 4a3 and the bottom-surface-side cooling flow path 4a4. The second flow path hole 4c is a flow path disposed at a portion of the case 17 on the second side surface 2d side, the flow path extending from the third side surface 2e side to the fourth side surface 2f side so as to be connected to the top-surface-side cooling flow path 4a3 and the bottom-surface-side cooling flow path 4a4.

The coolant flows in the flowing direction 10 through the first flow path hole 4b, the top-surface-side cooling flow path 4a3 or the bottom-surface-side cooling flow path 4a4, and the second flow path hole 4c in this order. Each case 17 is in contact with the cooler 4 at the side surface 17b provided with a seal structure for the periphery of an opened portion, and a flow path through which the coolant flows is sealed. The seal structure is implemented by, for example, an O ring. The power module 2 and each of at least a part of the first flow path hole 4b and at least a part of the second flow path hole 4c are located to overlap with each other as seen in a direction perpendicular to the first side surface 2c of the power module 2.

In the present embodiment, as shown in FIG. 25, the cooling fins 17a are provided also to portions, of the case 17, that are adjacent to the first flow path hole 4b and portions, of the case 17, that are adjacent to the second flow path hole 4c. However, the present disclosure is not limited to this configuration, and, as shown in FIG. 29, the cooling fins 17a may be partially excluded at the portions, of the case 17, that are adjacent to the first flow path hole 4b and the portions, of the case 17, that are adjacent to the second flow path hole 4c. If the cooling fins 17a are partially excluded, the coolant can be caused to flow unidirectionally, and thus the coolant can be caused to flow parallelly and evenly through the cooling fins 17a. Therefore, if a plurality of the power modules 2 are provided, the cooling capability is made uniform among the power modules 2, and the temperatures of the power modules 2 can be made equal to one another. Consequently, electrical characteristics of the power modules 2 having temperature characteristics become even among the power modules 2, and switching controllability of each power module 2 becomes favorable. In addition, it is possible to suppress reduction in cooling performance, vibrations, and impact which could be caused by uneven flow of the coolant. In addition, it is possible to prevent defects such as damage to the flow path.

The capacitor 3 may be disposed on the bottom surface 2a side of each power module 2. If the capacitor 3 is disposed on the bottom surface 2a side or the top surface 2b side of the power module 2, the capacitor 3 and the power module 2 can be disposed close to each other, and thus the electrical wiring between the power module 2 and the capacitor 3 can be shortened. Since the electrical wiring between the power module 2 and the capacitor 3 is shortened, reduction in the inductance of the power conversion device 1 can be realized. Since reduction in the inductance can be realized, the chip size of each power semiconductor is reduced, whereby cost for the power semiconductor can be reduced.

As described above, in the power conversion device 1 according to the eighth embodiment, the power module 2 and each of at least a part of the first flow path hole 4b and at least a part of the second flow path hole 4c are located to overlap with each other as seen in the direction perpendicular to the first side surface 2c of the power module 2. Thus, the projection area of the cooler 4 can be reduced. Since the projection area of the cooler 4 can be reduced, the size of the power conversion device 1 can be reduced. In addition, the cooler 4 includes the top-surface-side cooling flow paths 4a3 and the bottom-surface-side cooling flow paths 4a4, and thus each power module 2 can be cooled from both sides, whereby cooling capability for the power module 2 can be improved. Since cooling capability for the power module 2 is improved, a chip of each power semiconductor comes to have tolerance for heat. Thus, the chip size of the power semiconductor is reduced, whereby cost for the power semiconductor can be reduced.

In addition, if each top-surface-side cooling flow path 4a3 and the corresponding bottom-surface-side cooling flow path 4a4, and the first flow path hole 4b and the second flow path hole 4c, are located to overlap with each other, the volumes of the first flow path hole 4b and the second flow path hole 4c can be reduced. Thus, the size of the power conversion device 1 can be reduced.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the technical scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 power conversion device
2 power module
2a bottom surface
2b top surface
2c first side surface
2d second side surface
2e third side surface
2f fourth side surface
2g power terminal
2h control terminal
3 capacitor
3a bottom surface
3b top surface
3c first side surface
3d second side surface
3e third side surface
3f fourth side surface
3g power terminal
4 cooler
4a cooling flow path
4a1 outer peripheral portion
4a2 flow path surface
4a3 top-surface-side cooling flow path
4a4 bottom-surface-side cooling flow path
4b first flow path hole
4b1 stepped portion
4c second flow path hole
4d first coupling portion
4e second coupling portion
4f third flow path hole
4g opposing cooling flow path
4h third coupling portion
4i fourth coupling portion
5 cooling plate
5a cooling fin
5b one surface
5c another surface
6 lid
7 heat-dissipating resin
8 control board
8a control component
9 pipe
10 flowing direction
11 seal bolt
12 partition portion
13 partition portion
14 opposing power module
14a bottom surface
14b top surface
14c first side surface
14d second side surface
14g power terminal
14h control terminal
15 opposing cooling plate
15a cooling fin
15b one surface
15c another surface
16 opposing control board
16a control component
17 case
17a cooling fin
17b side surface
20 outer wall member

What is claimed is:

1. A power conversion device comprising:
a power module including a power semiconductor and having a shape of a rectangular parallelepiped having a bottom surface, a top surface, and four side surfaces;
a flat-shaped cooling plate having one surface thermally connected to the bottom surface of the power module; and
a cooler configured to cool the cooling plate, wherein
the cooler includes
a cooling flow path through which a coolant flows, along another surface of the cooling plate, from a first side surface side of the power module to a second side surface side thereof opposite to the first side surface,
a first flow path hole
disposed apart from the cooling flow path so as to be closer to an opposite side to the power module side than a portion of the cooling flow path on the first side surface side is, and
extending from a third side surface side of the power module adjacent to the first side surface to a fourth side surface side thereof opposite to the third side surface,
a second flow path hole
disposed apart from the cooling flow path so as to be closer to the opposite side to the power module side than a portion of the cooling flow path on the second side surface side is, and
extending from the third side surface side to the fourth side surface side,
a first coupling portion coupling the first flow path hole and the portion of the cooling flow path on the first side surface side, and
a second coupling portion coupling the second flow path hole and the portion of the cooling flow path on the second side surface side, and
the power module and each of at least a part of the first flow path hole and at least a part of the second flow path hole are located to overlap with each other as seen in a direction perpendicular to the one surface of the cooling plate.

2. The power conversion device according to claim 1, further comprising a plurality of the power modules having bottom surfaces thermally connected to the one surface of the cooling plate, the power modules being disposed side by side with the power module in a direction parallel to the first side surface so as to have a same orientation as an orientation of the power module, wherein
a total length of the plurality of the power modules on the first side surface side is longer than a length of each power module on the third side surface side.

3. The power conversion device according to claim 1, wherein the cooling plate further includes, on the other surface thereof, a cooling fin.

4. The power conversion device according to claim 1, wherein cross-sectional shapes, of one or both of the first flow path hole and the second flow path hole, that are perpendicular to directions in which the first flow path hole and the second flow path hole extend, are circular shapes.

5. The power conversion device according to claim 1, wherein sizes of cross-sectional shapes, of one or both of the first flow path hole and the second flow path hole, that are perpendicular to directions in which the first flow path hole and the second flow path hole extend, differ at portions between the third side surface side and the fourth side surface side.

6. The power conversion device according to claim 1, further comprising:
a capacitor electrically connected to the power module and disposed on the first side surface side, the second side surface side, or the top surface side of the power module; and
a control board configured to control an operation of the power module, wherein
the control board electrically connected to the power module is disposed to oppose the power module and the capacitor.

7. The power conversion device according to claim 6, wherein a power terminal exposed outward from the power module and a power terminal exposed outward from the capacitor are electrically connected between the control board and each of the power module and the capacitor.

8. The power conversion device according to claim 6, wherein
the capacitor is formed in a shape of a rectangular parallelepiped having a bottom surface, a top surface, and four side surfaces,
the capacitor is disposed on the first side surface side or the second side surface side of the power module, and the capacitor is disposed such that a second side surface thereof opposes the cooler,
a member forming a flow path of the cooler is formed integrally with an outer wall member enclosing a first side surface, a third side surface, a fourth side surface, and the bottom surface of the capacitor, and
an interval between the outer wall member and the bottom surface of the capacitor is filled with heat-dissipating resin.

9. The power conversion device according to claim 6, wherein
the capacitor is formed in a shape of a rectangular parallelepiped having a bottom surface, a top surface, and four side surfaces,
the capacitor is disposed on the first side surface side or the second side surface side of the power module, and the capacitor is disposed such that a second side surface thereof opposes the cooler,
a member forming a flow path of the cooler is formed integrally with an outer wall member enclosing a first side surface, a third side surface, a fourth side surface, and the bottom surface of the capacitor,
gaps are present between the outer wall member and the four side surfaces of the capacitor, and the gaps are filled with heat-dissipating resin, and
the outer wall member and the bottom surface of the capacitor are in contact with each other.

10. The power conversion device according to claim 6, wherein
the capacitor is disposed on the first side surface side of the power module, and
a coolant flows into the first flow path hole.

11. The power conversion device according to claim 1, wherein
a coolant outlet/inlet through which a coolant flows out/in is provided at a portion of the first flow path hole on the third side surface side or the fourth side surface side, and
a coolant outlet/inlet through which the coolant flows out/in is provided at a portion of the second flow path hole on the third side surface side or the fourth side surface side.

12. The power conversion device according to claim 1, wherein
the cooler further includes a third flow path hole coupled to the second flow path hole and extending from the second flow path hole to the second side surface side or an opposite side to the cooling flow path,
a coolant outlet/inlet through which a coolant flows out/in is provided at a portion of the first flow path hole on the third side surface side or the fourth side surface side, and
a coolant outlet/inlet through which the coolant flows out/in is provided at a portion of the third flow path hole on an opposite side to the second flow path hole side.

13. The power conversion device according to claim 1, wherein
each of the first flow path hole and the first coupling portion is partitioned at a position thereof between the third side surface side and the fourth side surface side,
the cooling flow path is partitioned at a position thereof, between the third side surface side and the fourth side surface side, that corresponds to the position at which each of the first flow path hole and the first coupling portion is partitioned, and
a coolant outlet/inlet through which a coolant flows out/in is provided at each of portions of the first flow path hole on the third side surface side and the fourth side surface side.

14. The power conversion device according to claim 11, wherein each of the cooling flow path, the first coupling portion, and the second coupling portion is partitioned at a plurality of positions thereof between the third side surface side and the fourth side surface side, along a direction in which a coolant flows.

15. The power conversion device according to claim 11, wherein a pipe is provided to each coolant outlet/inlet.

16. The power conversion device according to claim 15, wherein seal bolts close: an opening, of the first flow path hole, which is located on the third side surface side or the fourth side surface side and to which the corresponding pipe is not provided; and an opening, of the second flow path hole, which is located on the third side surface side or the fourth side surface side and to which the corresponding pipe is not provided.

17. The power conversion device according to claim 1, further comprising:
an opposing power module including a power semiconductor and having a shape of a rectangular parallelepiped having a bottom surface, a top surface, and four side surfaces; and
a flat-shaped opposing cooling plate having one surface thermally connected to the bottom surface of the opposing power module, wherein
the other surface of the cooling plate and another surface of the opposing cooling plate are located to oppose each other with the cooler interposed therebetween,
the first side surface side of the power module and a first side surface side of the opposing power module are located on a same side,
the cooler further includes
an opposing cooling flow path through which the coolant flows, along the other surface of the opposing cooling plate, from the first side surface side of the opposing power module to a second side surface side thereof opposite to the first side surface,
a third coupling portion coupling the first flow path hole and a portion of the opposing cooling flow path on the first side surface side, and
a fourth coupling portion coupling the second flow path hole and a portion of the opposing cooling flow path on the second side surface side, and
the opposing power module and each of at least a part of the first flow path hole and at least a part of the second flow path hole are located to overlap with each other as seen in a direction perpendicular to the other surface of the opposing cooling plate.

18. A power conversion device comprising:
a power module including a power semiconductor and having a shape of a rectangular parallelepiped having a bottom surface, a top surface, and four side surfaces;
a case in which the power module is accommodated; and
a cooler configured to cool the case, wherein
the cooler includes
a top-surface-side cooling flow path through which a coolant flows, along an outer surface of a wall of the case opposing the top surface of the power module, from a first side surface side of the power module to a second side surface side thereof opposite to the first side surface,
a bottom-surface-side cooling flow path through which the coolant flows, along an outer surface of a wall of the case opposing the bottom surface of the power module, from the first side surface side of the power module to the second side surface side thereof,
a first flow path hole
disposed apart from the top-surface-side cooling flow path and the bottom-surface-side cooling flow path so as to be closer to a third side surface side adjacent to the first side surface than portions of the top-surface-side cooling flow path and the bottom-surface-side cooling flow path on the first side surface side are, and
extending from the top surface side to the bottom surface side,
a second flow path hole
disposed apart from the top-surface-side cooling flow path and the bottom-surface-side cooling flow path so as to be closer to the third side surface side than portions of the top-surface-side cooling flow path and the bottom-surface-side cooling flow path on the second side surface side are, and
extending from the top surface side to the bottom surface side,
a first coupling portion coupling the first flow path hole and the portions of the top-surface-side cooling flow path and the bottom-surface-side cooling flow path on the first side surface side, and
a second coupling portion coupling the second flow path hole and the portions of the top-surface-side cooling flow path and the bottom-surface-side cooling flow path on the second side surface side, and
the power module and each of at least a part of the first flow path hole and at least a part of the second flow path hole are located to overlap with each other as seen in a direction perpendicular to the third side surface of the power module.

19. A power conversion device comprising:
a power module including a power semiconductor and having a shape of a rectangular parallelepiped having a bottom surface, a top surface, and four side surfaces;
a case in which the power module is accommodated; and
a cooler configured to cool the case, wherein
the cooler includes
a top-surface-side cooling flow path through which a coolant flows, along an outer surface of a wall of the case opposing the top surface of the power module, from a first side surface side of the power module to a second side surface side thereof opposite to the first side surface,
a bottom-surface-side cooling flow path through which the coolant flows, along an outer surface of a wall of the case opposing the bottom surface of the power module, from the first side surface side of the power module to the second side surface side thereof,
a first flow path hole disposed at a portion of the case on the first side surface side, the first flow path hole extending from a third side surface side adjacent to the first side surface to a fourth side surface side opposite to the third side surface so as to be connected to the top-surface-side cooling flow path and the bottom-surface-side cooling flow path, and
a second flow path hole disposed at a portion of the case on the second side surface side, the second flow path hole extending from the third side surface side to the fourth side surface side so as to be connected to the top-surface-side cooling flow path and the bottom-surface-side cooling flow path, and
the power module and each of at least a part of the first flow path hole and at least a part of the second flow path hole are located to overlap with each other as seen in a direction perpendicular to the first side surface of the power module.

20. The power conversion device according to claim 18, wherein the case includes a plurality of cooling fins on the outer surface of the wall thereof opposing the top surface of the power module and on the outer surface of the wall thereof opposing the bottom surface of the power module.

21. The power conversion device according to claim 20, wherein the cooling fins are partially excluded at a portion of the case adjacent to the first flow path hole and a portion of the case adjacent to the second flow path hole.

22. A manufacturing method for a power conversion device, the manufacturing method comprising:
a member preparation step of preparing
a power module including a power semiconductor and formed in a shape of a rectangular parallelepiped so as to have a bottom surface, a top surface, and four side surfaces, and
a flat-shaped cooling plate;
a cooler manufacturing step of manufacturing a cooler,
the cooler including
a cooling flow path through which a coolant flows, along one surface of the cooling plate, from a first side surface side of the power module to a second side surface side thereof opposite to the first side surface, in an assembled state,
a first flow path hole
disposed apart from the cooling flow path so as to be closer to an opposite side to the power module side than a portion of the cooling flow path on the first side surface side is, in the assembled state, and
extending from a third side surface side of the power module adjacent to the first side surface to a fourth side surface side thereof opposite to the third side surface, in the assembled state,
a second flow path hole
disposed apart from the cooling flow path so as to be closer to the opposite side to the power module side than a portion of the cooling flow path on the second side surface side is, in the assembled state, and
extending from the third side surface side to the fourth side surface side, in the assembled state,
a first coupling portion coupling the first flow path hole and the portion of the cooling flow path on the first side surface side, in the assembled state, and
a second coupling portion coupling the second flow path hole and the portion of the cooling flow path on the second side surface side, in the assembled state,
the power module and each of at least a part of the first flow path hole and at least a part of the second flow path hole being located to overlap with each other as seen in a direction perpendicular to another surface of the cooling plate, in the assembled state,
the cooler manufacturing step including
manufacturing each of the first flow path hole and the second flow path hole by using a pull-out core by die casting, and
manufacturing each of a portion constituting the cooling flow path, the first coupling portion, and the second coupling portion by using a fixed mold or a movable mold by die casting; and
a cooling flow path formation step of thermally connecting the bottom surface of the power module and the other surface of the cooling plate to each other, and joining the one surface of the cooling plate to an outer peripheral portion of the cooling flow path.

23. The manufacturing method for a power conversion device according to claim 22, wherein the member preparation step includes forming, on the cooling plate, a plurality of cooling fins protruding in a direction away from the one surface of the cooling plate with intervals between the cooling fins being narrowed by forging.

24. The manufacturing method for a power conversion device according to claim 22, wherein the cooling flow path formation step includes joining the one surface of the cooling plate and the outer peripheral portion of the cooling flow path to each other by metal joining.
